(19) United States
(12) Patent Application Publication
(10) Pub. No.: US 2006/0197088 A1
(43) Pub. Date: Sep. 7, 2006

(54) Semiconductor device and manufacturing method of the same

(75) Inventors: Atsuo Isobe, Atsugi (JP); Hajime Tokunaga, Atsugi (JP); Mayumi Yamaguchi, Atsugi (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/367,509

(22) Filed: Mar. 6, 2006

(30) Foreign Application Priority Data
Mar. 7, 2005 (JP) 2005-062929

(51) Int. Cl. H01L 29/04

(52) U.S. Cl. 257/59

(57) ABSTRACT

It is an object of the present invention to manufacture a minute TFT having an LDD region through process with the reduced manufacturing steps, and form a TFT having a structure suitable for each circuit. It is also an object of the present invention to secure an ON current even in a TFT having an LDD region. A hat-shaped gate electrode is formed by forming a two-layer gate electrode in which the gate length of a lower layer of the gate electrode is longer than that of an upper layer of the gate electrode. The hat-shaped gate electrode is formed by etching only the upper layer of the gate electrode by making the use of the resist recess width. In addition, silicide is formed in a contact portion of a wiring and a semiconductor film to lower contact resistance.

### BACKGROUND OF THE INVENTION

1. Field of the Invention

The present invention relates to a semiconductor device forming various circuits and a manufacturing method of the semiconductor device.

2. Related Art

A conventional thin film transistor (hereinafter, referred to as a TFT) is formed by using an amorphous semiconductor film; therefore, it was almost impossible to obtain a TFT having field effect mobility of 10 cm²/V·Sec or more. However, a TFT having high filed effect mobility can be obtained owing to the appearance of a TFT formed by using a crystalline semiconductor film.

Since the TFT formed by using a crystalline semiconductor film has high field effect mobility, various functional circuits can be formed over the same substrate concurrently by using the TFT. For example, in a display device, a driver IC and the like are mounted on a display portion to have a driver circuit previously. On the other hand, by using the TFTs formed by using crystalline semiconductor films, a display portion and a driver circuit formed of a shift register circuit, a level shifter circuit, a buffer circuit, a sampling circuit, and the like can be disposed over the same substrate. The driver circuit is basically formed by a CMOS circuit including an n-channel TFT and a p-channel TFT.

In order to form various circuits over the same substrate, it is necessary to form a TFT corresponding to each of the circuits. This is because, considering the case of a display device, operating conditions of a TFT in a pixel portion are not always identical to those of a TFT in a driver circuit, and each TFT is thus required to have different characteristics. A TFT in a pixel portion formed of an n-channel TFT is used as a switching element to apply a voltage to liquid crystals for driving. The TFT in a pixel portion is required to have the sufficiently low OFF current value in order to store a charge accumulated in a liquid crystal layer within one frame period. On the other hand, a buffer circuit and the like in a driver circuit are applied with a high drive voltage; therefore, it is necessary to increase a withstand voltage so that elements in the driver circuit are not broken even when the high voltage is applied. In addition, in order to enhance ON current drive capacity, it is necessary to secure the ON current value sufficiently.

As a structure of a TFT for reducing the OFF current value, there is a structure having a low-concentration drain region (hereinafter also referred to as an LDD region). This structure has a region doped with an impurity element in a low concentration between a channel formation region and a source region or a drain region that is doped with an impurity element in a high concentration. In addition, there is a so-called GOLD (Gate Overlapped LDD) structure in which an LDD region is formed to overlap with a gate electrode with a gate insulating film interposed therebetween as a means for preventing deterioration in the ON current value due to hot carriers. In accordance with such a structure, a high electric field in the vicinity of a drain is relieved; therefore, it becomes possible to reduce deterioration in the ON current value due to hot carriers. It is to be noted that an LDD region which does not overlap with the gate electrode is referred to as a Loff region, while an LDD region which overlaps with the gate electrode with the gate insulating film interposed therebetween is referred to as a Lov region.

Here, the Loff region works effectively in suppressing the OFF current value, whereas it does not work effectively in preventing deterioration in the ON current value due to hot carriers by relieving the electric field in the vicinity of the drain. On the other hand, the Lov region works effectively in preventing deterioration in the ON current value by relieving the electric field in the vicinity of the drain; however, it does not work effectively in suppressing the OFF current value. Thus, it is necessary to form a TFT having a structure corresponding to appropriate TFT characteristics required for each of the various circuits.

As one of the methods for manufacturing TFTs having various structures concurrently over the same substrate, there is a method to use a so-called hat-shaped gate electrode of a two-layer structure, in which the gate length of a bottom layer is longer than that of an upper layer, and form a plurality of TFTs each having an LDD region concurrently over the same substrate (for example, see Reference 1: Japanese Patent Application Laid-Open No. 2004-179330 (see FIGS. 5 to 8)). FIGS. 33A to 33D show the manufacturing method.

First, a base insulating film 2, a semiconductor film 3, a gate insulating film 4, a first conductive film 5 which becomes a gate electrode, and a second conductive film 6 which becomes a gate electrode are stacked sequentially over a substrate 1, and a resist mask 7 is formed over the second conductive film (FIG. 33A). Next, the first conductive film and the second conductive film are etched by dry etching to have side faces with a taper shape, and gate electrodes 8 and 9 are formed (FIG. 33B). Subsequently, the gate electrode 9 is processed by anisotropic etching. Accordingly, a hat-shaped gate electrode in which a cross-sectional shape is like a hat is formed (FIG. 33C). Thereafter, by conducting doping of an impurity element about twice, LDD regions 10a below the gate electrode 8, high-concentration impurity regions 10b on both ends of the semiconductor film in contact with the LDD regions, and a channel formation region 10c are formed (FIG. 33D).

On the other hand, as for an ON current, there is also a method of reducing contact resistance that is parasitic resistance of a TFT to increase an ON current. Specifically, nickel silicide is provided in a source region and a drain region to reduce contact resistance to a wiring (for example, see Reference 2: Japanese Patent Application Laid-Open No. Hei 10-98199).

At present, research on a submicron TFT is actively carried out. However, it is difficult to form a minute TFT suitable for various circuits by using the method described in Reference 1. This is because it is difficult to shorten the length of the LDD region in a gate length direction (hereinafter, referred to as the LDD length) up to a desired value. As shown in FIGS. 33A to 33D, Reference 1 shows a method in which the taper side faces of the gate electrode 9 are etched to form a hat-shaped gate electrode, and the LDD regions 10a are formed by doping. Therefore, when a taper angle (θ) of the side face of the gate electrode 9 shown in FIG. 33B is made close to 90°, the LDD length gets shorter. However, it is difficult to adjust the taper angle, and on the other hand, when θ is 90°, the LDD region itself cannot be formed; therefore, it is difficult to form the LDD length of a certain value or less.

In addition, while the LDD region suppresses hot carriers or short channel effect, it functions as resistance against an ON current as well. Therefore, in each TFT, there is such an optimum LDD length by which a desired ON-current can be obtained as well as hot carriers and the like are suppressed. However, in the conventional method, although the gate length and the length of a semiconductor film can be formed in a submicron size by etching, an LDD region having the LDD length suitable for that size cannot be provided. Thus, a submicron TFT having preferable characteristics cannot be obtained.

In addition, there is also a problem that an influence of parasitic resistance due to an LDD region grows when a TFT is miniaturized.

As described above, it is an object of the present invention to reduce an influence of parasitic resistance due to an LDD region even in a miniaturized TFT. It is also an object of the present invention to make a structure of a TFT suitable for the function of the various circuits even in a miniaturized TFT, and improve operating characteristics and reliability of a semiconductor device. In addition, it is an object to reduce a manufacturing cost and improve the yield by reducing the number of manufacturing steps.

### SUMMARY OF THE INVENTION

According to one feature of the present invention, a semiconductor film, which is formed over a substrate, including a channel formation region, a first low-concentration impurity region, a second low-concentration impurity region, and a high-concentration impurity region is provided; a gate insulating film formed over at least the channel formation region, the first low-concentration impurity region and the second low-concentration impurity region is provided; a gate electrode, which is formed over the gate insulating film, including a first conductive film and a second conductive film formed over the first conductive film is provided; sidewalls formed on side surfaces of the gate electrode are provided; a silicide layer formed over a surface of the high-concentration impurity region is provided; and a wiring connected to the silicide layer is provided, where the first conductive film and the second conductive film form a hat-shaped gate electrode; a side edge of the gate insulating film in a channel length direction and an outer side edge of one of the sidewalls are in alignment; the first low-concentration impurity region is a Lov region which overlaps with the first conductive film with the gate insulating film interposed therebetween, and does not overlap with the second conductive film; and the second low-concentration impurity region is a Loff region which overlaps with one of the sidewalls with the gate insulating film interposed therebetween, and does not overlap with the first conductive film.

According to another feature of the present invention: a gate insulating film, a first conductive film, and a second conductive film are sequentially formed over a semiconductor film over a substrate; a resist is formed over the second conductive film; an etched second conductive film is formed by conducting a first etching to the second conductive film by using the resist as a mask; a first gate electrode is formed by conducting a second etching to the first conductive film; a second gate electrode having the shorter length in a channel length direction than that of the first gate electrode is formed by conducting a third etching to the etched second conductive film to recess the resist and etch the etched second conductive film by using the recessed resist as a mask; sidewalls are formed on side surfaces of the first gate electrode and side surfaces of the second gate electrode; a silicide layer is formed in a part of the semiconductor film that is exposed from the gate insulating film after exposing a part of the semiconductor film by etching the gate insulating film using the sidewalls and the second gate electrode as masks; and a wiring connected to the silicide layer is formed.

According to another feature of the present invention, the resist is recessed in the second etching.

According to another feature of the present invention, after forming the second gate electrode, doping of an impurity element is conducted by using the second gate electrode as a mask to form a channel formation region and a low-concentration impurity region that is in contact with the channel formation region in the semiconductor film; sidewalls are formed; doping of an impurity element is conducted by using the sidewalls and the second gate electrode as masks to selectively form a high-concentration impurity region in the low-concentration impurity region; and a silicide layer is formed after forming the high-concentration impurity region.

According to another feature of the present invention, by conducting doping using the sidewalls and the second gate electrode as masks, the low-concentration impurity region is disposed below the sidewall with the gate insulating film interposed therebetween as well as being disposed below a portion of the first gate electrode, which does not overlap with the second gate electrode, with the gate insulating film interposed therebetween.

According to another feature of the present invention, after forming the second gate electrode, doping of an impurity element is conducted by using the second gate electrode as a mask to form a channel formation region and a low-concentration impurity region that is in contact with the channel formation region in the semiconductor film; and sidewalls are formed after doping of an impurity element using the first gate electrode as a mask to selectively form a high-concentration impurity region in the low-concentration impurity region.

According to another feature of the present invention, after forming the second gate electrode, doping of an impurity element is conducted by using the second gate electrode as a mask to form a channel formation region and a low-concentration impurity region that is in contact with the channel formation region in the semiconductor film; doping of an impurity element is conducted by using the first gate electrode as a mask to selectively form a high-concentration impurity region in the low-concentration impurity region; the first gate electrode is etched by using the second gate electrode as a mask to form a third gate electrode having the same length in a channel length direction as the second gate electrode; and sidewalls are formed.

According to another feature of the present invention, the etched second conductive film is formed to have a taper angle of the side face of 80°≦θ≦90°, namely, the etched second conductive film is formed to have an almost perpendicular taper angle.

According to another feature of the present invention, the first conductive film is a TaN film. According to another feature of the present invention, the second conductive film is a W film. In addition, the first to third etchings are conducted by dry etching.

A method for forming a hat-shaped gate electrode according to the present invention is different from the forming method shown in FIGS. 33A to 33D in which a taper portion of a gate electrode 9 is utilized. According to the present invention, by making the use of the resist recess width in etching, etching is conducted so that the gate length of the second gate electrode is shorter than that of the first gate electrode, and a hat-shaped gate electrode is formed. The resist recess width in etching of the present invention is a resist recess width in the third etching for etching the etched second conductive film. Alternatively, there is also a case where the resist is etched at the same time as the second etching for forming the first gate electrode; thus, the resist recess width is also a width including resist recess widths in the second and the third etchings.

In addition, doping of an impurity element is conducted to the semiconductor film by using the hat-shaped gate electrode formed in the present invention as a mask, and thus, various semiconductor devices having a Lov region or a Loff region can be manufactured over the same substrate.

In addition, after forming the hat-shaped gate electrode, common sidewalls to the side surfaces of the first and the second gate electrodes are formed to cover the side surfaces of the both gate electrodes. By conducting doping of an impurity element using the sidewalls and the second gate electrode as masks, a semiconductor device having both of a Lov region and a Loff region can be manufactured.

A taper angle of the side face of the etched second gate conductive film formed in the first etching of the present invention is 80° to 90°.

The LDD length of an LDD region of the present invention is 10 nm or more to 300 nm or less, preferably, 50 nm or more to 200 nm or less. The length of a Lov region in a channel length direction (hereinafter referred to as the Lov length) is 20 nm or more to 200 nm or less, and the length of a Loff region in a channel length direction (hereinafter referred to as the Loff length) is 30 nm or more to 500 nm or less. Further, the channel length of the channel formation region of the present invention is in a rage of 0.1 μm or more to 1.0 μm or less.

In the present specification, a hat-shaped gate electrode is a gate electrode having a stacked layer structure of at least two layers. The gate length (the length in a channel length direction) of a lower layer of the gate electrode is longer than the gate length (the length in a channel length direction) of an upper layer of the gate electrode. In addition, a thickness of the upper layer of the gate electrode is thicker than a thickness of the lower layer of the gate electrode. A cross-sectional shape of the lower gate electrode layer may be a shape widened toward the lower side, or a rectangle shape.

In accordance with the present invention, a minute hat-shaped gate electrode can be formed, and by conducting doping of an impurity element using the gate electrode as a mask, an LDD region having the LDD length that has not been achieved before can be formed. Therefore, a semiconductor device having favorable operating characteristics and high reliability can be achieved even when miniaturized, and semiconductor devices suitable for various circuits can be formed. In addition, since semiconductor devices having various structures can be manufactured through process having the reduced manufacturing steps, a manufacturing cost can be reduced and the yield can be improved.

In addition, since silicide is formed in a part of a semiconductor film, and a wiring and the semiconductor film are connected through the silicide, contact resistance can be lowered. Therefore, an ON current can be increased, and a desired ON current can be obtained even in a miniaturized TFT having an LDD region.

Further, a submicron TFT having a desired size can be formed without limitation in size so that a semiconductor device itself can be extremely compact and lightweight. In addition, the LDD length suitable for each TFT can be designed so that a semiconductor device can be obtained, which can suppress short channel effect and increase a withstand voltage as well as secure a desired ON current.

In addition, by forming sidewalls on a hat-shaped gate electrode and conducting doping of an impurity element, a highly reliable semiconductor device which has both of a Loff region and a Lov region and suppresses short channel effect can be obtained.

By conducting doping of an impurity element using the hat-shaped gate electrode according to the present invention as a mask, an LDD region can be formed, which has the extremely short LDD length of 10 to 300 nm, preferably, 50 to 200 nm. In particular, the Lov length can be 20 to 200 nm, and the length of the Loff region in a channel length direction (the Loff length) can be 30 to 500 nm. In addition, as for a minute TFT having the channel length of 0.1 to 1.0 μm, a TFT having an LDD region suitable for its TFT size can be formed. These and other objects, features and advantages of the present invention will become more apparent upon reading of the following detailed description along with the accompanied drawings.

### BRIEF DESCRIPTION OF THE DRAWINGS

In the accompanying drawings:

FIGS. 1A to 1D are views illustrating Embodiment 1 of the present invention;

FIGS. 2A to 2H are views illustrating Embodiment 1 of the present invention;

FIGS. 3A to 3D are views illustrating Embodiment 1 of the present invention;

FIGS. 4A to 4C are views illustrating Embodiment 1 of the present invention;

FIGS. 5A to 5F are views illustrating Embodiment 2 of the present invention;

FIGS. 6A to 6F are views illustrating Embodiment 3 of the present invention;

FIGS. 7A to 7F are views illustrating Embodiment 4 of the present invention;

FIGS. 8A to 8E are views illustrating Embodiment 5 of the present invention;

FIGS. 9A to 9E are views illustrating Embodiment 6 of the present invention;

FIGS. 10A to 10C are views illustrating Embodiment 7 of the present invention;

FIGS. 11A to 11F are views illustrating Embodiment 8 of the present invention;

FIG. 12 is a view illustrating Embodiment 9 of the present invention;

FIGS. 13A to 13D are views illustrating Embodiment 9 of the present invention;

FIG. 14 is a diagram describing Embodiment 9 of the present invention;

FIG. 15 is a view illustrating Embodiment 9 of the present invention;

FIGS. 16A to 16C are views illustrating Embodiment 9 of the present invention;

FIGS. 17A to 17D are views illustrating Embodiment 10 of the present invention;

FIGS. 18A and 18B are views illustrating Embodiment 10 of the present invention;

FIGS. 19A to 19D are views illustrating Embodiment 10 of the present invention;

FIGS. 20A to 20E are views illustrating Embodiment 10 of the present invention;

FIGS. 21A and 21B are views illustrating Embodiment 10 of the present invention;

FIGS. 22A to 22C are views illustrating Embodiment 11 of the present invention;

FIGS. 23A to 23C are views illustrating Embodiment 11 of the present invention;

FIGS. 24A to 24C are views illustrating Embodiment 11 of the present invention;

FIGS. 25A and 25B are views illustrating Embodiment 11 of the present invention;

FIG. 26 is a view illustrating Embodiment 11 of the present invention;

FIGS. 27A and 27B are views illustrating Embodiment 12 of the present invention;

FIG. 28 is a view illustrating Embodiment 12 of the present invention;

FIGS. 29A and 29B are SEM photographs of a cross-section of a hat-shaped gate electrode formed in Embodiment 1 of the present invention;

FIG. 30 is a SEM photograph of a cross-section of a hat-shaped gate electrode formed in Embodiment 1 of the present invention;

FIGS. 31A to 31D are views illustrating Example 1 of the present invention;

FIGS. 32A to 32D are views illustrating Example 1 of the present invention;

FIGS. 33A to 33D are views illustrating a conventional example;

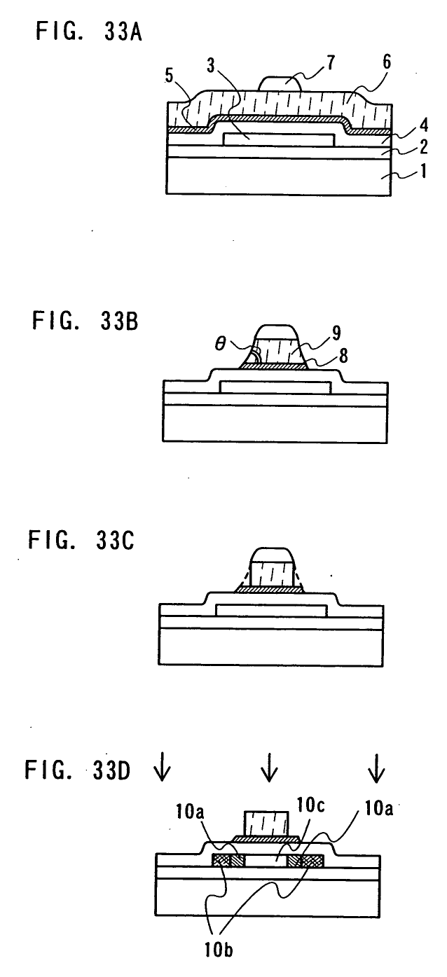

FIGS. 34A to 34G are views illustrating Embodiment 13 of the present invention; and

FIGS. 35A to 35D are graphs showing data of an experiment.

### DESCRIPTION OF THE INVENTION

Hereinafter, Embodiments of the present invention will be described with reference to the accompanying drawings. However, the present invention can be implemented in many various modes, and it is to be easily understood that various changes and modifications for the modes and details thereof will be apparent to those skilled in the art unless otherwise such changes and modifications depart from the spirit and the scope of the invention. Therefore, the present invention should not be construed as being limited to what is described in the Embodiments.

In addition, Embodiments 1 to 13 that will be described below can be arbitrarily combined within a practicable range.

### Embodiment 1

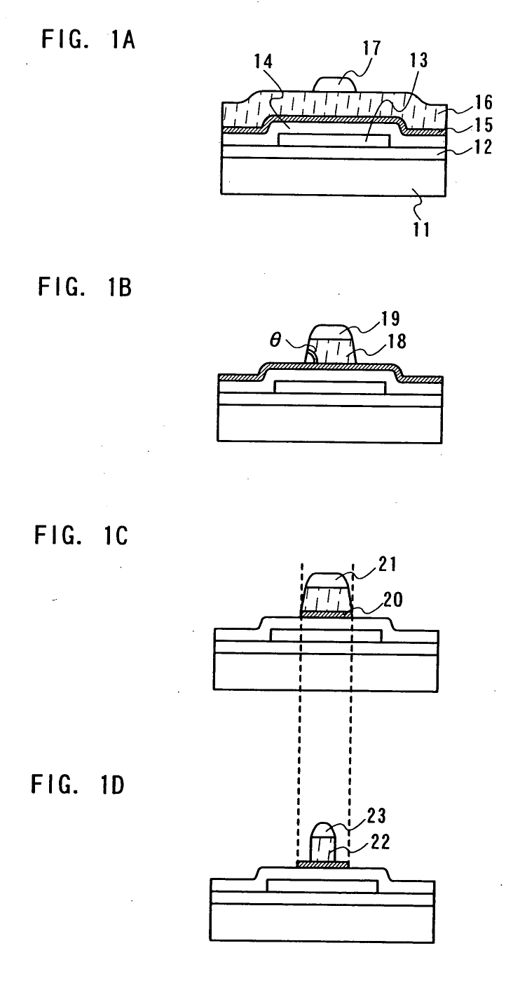

Hereinafter, a method for manufacturing a semiconductor device in accordance with Embodiment 1 will be described with reference to FIGS. 1A to 1D, 2A to 2H, 3A to 3D, and 4A to 4C. A TFT used in the semiconductor device of the present embodiment has a Lov region and a Loff region as an LDD region.

First, over a substrate 11, a base insulating film 12 is formed to be 100 to 300 nm thick. As the substrate 11, an insulating substrate such as a glass substrate, a quartz substrate, a plastic substrate or a ceramic substrate; a metal substrate; a semiconductor substrate; or the like can be used.

The base insulating film 12 can be formed by using a single layer structure of an insulating film containing oxygen or nitrogen such as silicon oxide (SiOx), silicon nitride (SiNx), silicon oxide containing nitrogen (SiOxNy) (x>y) (also referred to as silicon oxynitride), or silicon nitride containing oxygen (SiNxOy) (x>y) (also referred to as silicon nitride oxide), or a staked structure thereof. In particular, it is preferable to form a base insulating film when impurities from a substrate are concerned.

In addition, when the base insulating film 12 is a staked structure, it is preferable that a portion of the base insulating film that is in contact with a semiconductor film is a silicon nitride film or a silicon nitride oxide film having a film thickness of 10 to 200 nm, preferably, 50 to 150 nm. In a subsequent crystallization step, when a crystallization method in which a metal element is added into a semiconductor film is used, gettering of the metal element is necessary. In that case, when the base insulating film is a silicon oxide film, in an interface between the silicon oxide film and a silicon film of the semiconductor film, a metal element in the silicon film and oxygen in the silicon oxide film react with each other to be metal oxide, and the metal element may be unlikely to be gettered. Thus, it is preferable that a silicon oxide film is not used for the base insulating film that is in contact with the semiconductor film.

Subsequently, a semiconductor film is formed to be 10 to 100 nm thick. A material for the semiconductor film can be selected in accordance with the required characteristics of a TFT, and any of a silicon film, a silicon germanium film, and a silicon carbide film may be used. As the semiconductor film, it is preferable to use a crystalline semiconductor film that is crystallized by a laser crystallization method using an excimer laser or the like after forming an amorphous semiconductor film or a microcrystal semiconductor film. The microcrystal semiconductor film can be obtained by glow discharge decomposition of silicide such as SiH₄. The microcrystal semiconductor film can be easily formed by diluting silicide with hydrogen or a rare gas element of fluorine.

In addition, it is also possible to apply a rapid thermal annealing (RTA) method using a halogen lamp or a crystallization technique using a heating furnace as the crystallization technique. Further, a method may also be used, in which a metal element such as nickel is added into an amorphous semiconductor film to have solid-phase growth of the added metal as a crystal nucleus.

Then, an island-shaped semiconductor film 13 is formed by processing the semiconductor film by etching. A gate insulating film 14 is formed to be 1 to 200 nm thick, preferably, 5 to 50 nm thick so as to cover the island-shaped semiconductor film 13.

The gate insulating film 14 may have a stacked structure by appropriately combining any of silicon oxide (SiOx), silicon nitride (SiNx), silicon oxide containing nitrogen (SiOxNy) (x>y), silicon nitride containing oxygen (SiNxOy) (x>y), and the like by CVD or sputtering. In the present embodiment, the gate insulating film 14 has a stacked structure of a SiNxOy film and a SiOxNy film.

Next, a first conductive film 15 and a second conductive film 16, which become a gate electrode, are formed over the gate insulating film 14. First, the first conductive film 15 is formed to be 5 to 50 nm thick. As the first conductive film 15, an aluminum (Al) film, a copper (Cu) film, a film containing aluminum or copper as its main component, a chromium (Cr) film, a tantalum (Ta) film, a tantalum nitride (TaN) film, a titanium (Ti) film, a tungsten (W) film, a molybdenum (Mo) film, or the like can be used. The second conductive film 16 is formed thereover to be 150 to 500 nm thick. As the second conductive film 16, for example, a chromium (Cr) film, a tantalum (Ta) film, a film containing tantalum as its main component, a titanium (Ti) film, a tungsten (W) film, an aluminum (Al) film, or the like can be used. It is to be noted that the first conductive film 15 and the second conductive film 16 are required to be a combination in which, in etching each film, one film has a selective ratio to the other film. As a combination of the first conductive film and the second conductive film, in which each film has a selective ratio to the other, for example, a combination of Al and Ta, Al and Ti, or TaN and W can be used. In the present embodiment, the first conductive film 15 is TaN and the second conductive film 16 is W.

Subsequently, a first resist 17 is formed over the second conductive film by photolithography with the use of a photo mask (FIG. 1A). The first resist 17 may be formed in a shape having a taper angle on a side face thereof. By the first resist 17 having a taper angle, a second conductive film 18 that is etched and has a taper angle θ can be formed in a first etching that is conducted subsequently. In addition, by the taper angle on the side face of the first resist 17, a reaction product in the first etching can be prevented from attaching to the side face of the first resist 17 and from growing. Further, by conducting a heat treatment to the first resist 17, the first resist 17 may also be formed so as to have a symmetrical cross-sectional shape having the same taper angles on both side faces of the resist.

Then, the first etching is conducted by using the first resist 17 as a mask (FIG. 1B). In the first etching, the second conductive film 16 is etched, and the etched second conductive film 18 is formed. At this time, it is preferable to conduct etching under an etching condition of a high selective ratio with respect to the first conductive film 15 so as not to etch the first conductive film 15. It is to be noted that the first resist 17 is also etched to be a second resist 19. However, the recess width of the first resist 17 to the second resist 19 is not shown in the drawing. At this time, the side face of the etched second conductive film 18 has a taper angle θ of 80°≧θ≧90°, which is nearly a perpendicular taper angle.

In the first etching, a mixed gas of Cl₂, SF₆, and O₂ is used as an etching gas, and the flow rate is Cl₂/SF₆/O₂=33/33/10 (sccm). Plasma is generated by adjusting pressure to be 0.67 Pa and applying power of 2000 W to a coil-shaped electrode. Power of 50 W is applied to a substrate side (sample stage).

Next, a second etching is conducted to the first conductive film by using the etched second conductive film 18 as a mask (FIG. 1C). By the second etching, a first gate electrode 20 is formed from the first conductive film 15. At this time, it is F preferable to conduct etching under an etching condition of a high selective ratio with respect to the gate insulating film 14 so as not to etch the gate insulating film 14. In the second etching condition, plasma is generated by applying power of 2000 W to a coil-shaped electrode at pressure of 0.67 Pa, and then, power of 50 W is applied to the substrate side (sample stage). An etching gas is Cl₂. It is to be noted that the second resist 19 is also etched and recessed to be a third resist 21; however, the recessed state is not shown in the drawing.

Then, a third etching is conducted (FIG. 1D). In the third etching condition, plasma is generated by applying power of 2000 W to a coil-shaped electrode at pressure of 1.33 Pa. Power is not applied to the substrate side (sample stage). An etching gas is a mixed gas of Cl₂, SF₆, and O₂, and the flow rate is Cl₂/SF₆/O₂=22/22/30 sccm. By the third etching, while the third resist 21 is recessed, the length of the etched second conductive film 18 in a channel length direction is shortened by using the recessed third resist 21 as a mask, and a second gate electrode 22 is formed. It is to be noted that the recessed third resist 21 becomes a fourth resist 23. Thereafter, the fourth resist 23 is removed.

Another third etching condition may be as follows: ICP/Bias=750 W/0 W, pressure: 0.67 Pa, an etching gas: a mixed gas of Cl₂, SF₆, and O₂, and the flow rate: Cl₂/SF₆/O₂=20/100/30 (sccm). Under this condition, a selective ratio of W, which is a material for the second gate electrode, to the gate insulating film 14 becomes higher; thus, the gate insulating film 14 can be prevented from being etched during the third etching.

In the third etching, a side face of the second gate electrode 22 tends to be easily etched. When the side face of the second gate electrode 22 is etched, the gate length (the length in a channel length direction) in the middle gets shorter than that of an upper surface or a lower surface; thus, a cross-section of the second gate electrode has a shape constricted in the middle. Accordingly, the coverage of a film formed over the second gate electrode 22 gets worse; thus, disconnection is easily caused. In addition, since the second gate electrode is used as a doping mask in forming an LDD region, it becomes difficult to control the LDD length. This etching on the side face is a phenomenon which occurs when the etching rate of the second gate electrode with respect to the etching rate of the resist is high. Therefore, in the present embodiment, the etching rate of the second gate electrode is lowered by setting a sample stage temperature to be low such as −10° C. or less; thus, the side-etching can be suppressed.

Through the above steps, a shape of a hat-shaped gate electrode is obtained. A hat-shaped structure of the present invention is obtained by making the use of the resist recess width in etching. Specifically, the recess width of the third resist 21 to the fourth resist 23 in the third etching is a difference between the gate length of the first gate electrode and that of the second gate electrode. Alternatively, the total of recess widths of the resist in the second etching and the third etching, in other words, the recess width of the second resist 19 to the fourth resist 23 is a difference between the gate length of the first gate electrode and that of the second gate electrode.

In accordance with a method for manufacturing a hat-shaped gate electrode of the present invention, the difference between the gate length of the first gate electrode and that of the second gate electrode (the Lov length) can be 20 to 200 nm; thus, an extremely minute gate electrode structure can be formed.

The first to third etchings of the present embodiment can be conducted by dry etching, and specifically, an ICP (Inductively Coupled Plasma) etching method can be used.

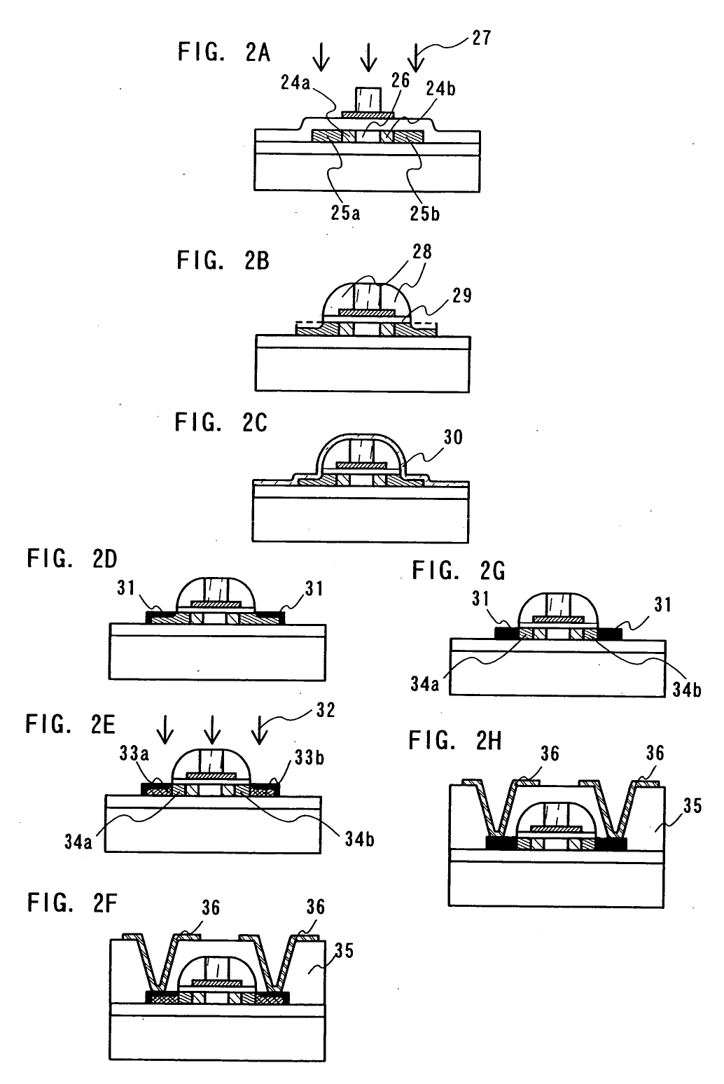

Next, doping of an impurity ion 27 is conducted to the island-shaped semiconductor film 13 (FIG. 2A). The island-shaped semiconductor film 13 is doped with an impurity element through the first gate electrode and the gate insulating film to form low-concentration impurity regions 24a and 24b in the island-shaped semiconductor film overlapping with the first gate electrode by using the second gate electrode as a mask. In addition, at the same time, both end portions of the island-shaped semiconductor film are also doped with an impurity element only through the gate insulating film to form low-concentration impurity regions 25a and 25b. A channel-formation region 26 is also formed. The element concentrations of the low-concentration impurity regions 24a, 24b, 25a, and 25b are each 1×10¹⁶ to 1×10²⁰ atoms/cm³ (preferably, 1×10¹⁶ to 5×10¹⁸ atoms/cm³). Ion doping or ion implantation can be used as the doping method. For example, boron (B), gallium (Ga), or the like is used as the impurity element in manufacturing a p-type semiconductor, whereas phosphorus (P), arsenic (As), or the like is used in manufacturing an n-type semiconductor.

The doping to the low-concentration impurity regions 24a and 24b is conducted not only through the gate insulating film but also through the first gate electrode 20. Therefore, the concentration of the impurity element of the low-concentration impurity regions 24a and 24b is lower than that of the low-concentration impurity regions 25a and 25b.

Then, an insulating layer is formed to cover the gate insulating film 14, the first gate electrode, and the second gate electrode. The insulating layer is formed by depositing silicon oxide containing nitrogen (SiOxNy) (x>y) film of 100 nm thick by plasma CVD, and then, a silicon oxide (SiO₂) film of 200 nm thick by thermal CVD.

Subsequently, the insulating layer is selectively etched by anisotropic etching mainly in a perpendicular direction to form a pair of insulating layers (hereinafter referred to as a sidewall) 28 which is in contact with side surfaces of the first gate electrode 20 and the second gate electrode 22 (FIG. 2B). The sidewalls 28 are used as masks to form silicide later. In addition, by this etching, a part of the gate insulating film is also removed to form a gate insulating film 29 and a part of the semiconductor film is exposed. The exposed parts of the semiconductor film become a source region and a drain region later. When an etching selective ratio of the insulating film and the semiconductor film is low, the exposed semiconductor film is etched to some extent, and a film thickness thereof becomes thin.

Next, after a natural oxide film formed over the surface of the exposed part of the semiconductor film is removed, a metal film 30 is formed (FIG. 2C). The metal film 30 is formed by using a material which reacts with the semiconductor film to form silicide. As the metal film, for example, a nickel film, a titanium film, a cobalt film, a platinum film, or a film composed of an alloy including at least two kinds of these elements, or the like can be given. In the present embodiment, a nickel film is used as the metal film 30, and the nickel film is formed by sputtering at a room temperature by deposition power of 500 W to 1 kW to have a film thickness of, e.g. 10 nm.

After the nickel film is formed, a silicide layer 31 is formed by a heat treatment. The silicide layer 31 is nickel silicide here. As the heat treatment, RTA, furnace annealing, or the like can be used. At this time, by controlling a film thickness of the metal film 30, a heating temperature, and a heating time, any structure of FIG. 2D or 2G can be obtained. For example, the structure of FIG. 2G can be obtained by a technique of forming a metal film so as to have a film thickness that is equal to or more than half of that of the semiconductor film; a higher heating temperature; or a longer heating time.

Then, nickel which has not reacted is removed. Here, nickel which has not reacted is removed by using an etching solution composed of HCl:HNO₃:H₂O=3:2:1.

Then, after the silicide layer 31 is formed so as to have a film thickness that is equal to or less than that of the semiconductor film as shown in FIG. 2D, doping of an impurity ion 32 is conducted by using the sidewalls 28 and the second gate electrode 22 as masks. By this doping, high-concentration impurity regions 33a and 33b are formed, which function as a source region and a drain region. The high-concentration impurity regions 33a and 33b are doped with an impurity element so that the concentration is 1×10¹⁹ to 1×10²¹ atoms/cm³. At the same time, low-concentration impurity regions 34a and 34b are formed. Ion doping or ion implantation can be used as the doping method. Boron (B), gallium (Ga), or the like is used as the impurity element in manufacturing a p-type semiconductor, whereas phosphorus (P), arsenic (As), or the like is used in manufacturing an n-type semiconductor.

Thereafter, an interlayer insulating film 35 is formed (FIG. 2F). The interlayer insulating film 35 is formed by using an organic material or an inorganic material. The interlayer insulating film 35 may have a single layer structure or a stacked structure. A contact hole is formed by etching in the interlayer insulating film 35 to expose the silicide layer 31. Then, a conductive layer is formed so that the contact hole is filled and etched to form a wiring 36.

On the other hand, after a whole film thickness of the semiconductor film becomes silicide as shown in FIG. 2G, similarly to FIG. 2F, an interlayer insulating film 35 is formed, and a wiring 36 is formed to obtain a structure of FIG. 2H. In FIG. 2H, a source region and a drain region made of the silicide layer 31 can be formed.

Before the interlayer insulating film is formed, or after a first layer film or a second layer film is formed in the case of a stacked interlayer insulating film, thermal activation of the impurity regions may be conducted. Laser light irradiation, RTA, a heat treatment using a furnace or the like can be used as the thermal activation. Since silicide is used to establish a contact to a wiring in this structure, a step of thermal activation of the impurity region can also be omitted.

In the structure of the present embodiment of FIG. 2F, the high-concentration impurity regions 33a and 33b become a source region and a drain region later. In addition, the low-concentration impurity regions 34a and 34b, which are parts of the semiconductor film overlapping with the bottom surfaces of the sidewalls formed on the side surfaces of the first gate electrode 20 with the gate insulating film 29 interposed therebetween, become Loff regions. Further, the low-concentration impurity regions 24a and 24b, which overlap with the first gate electrode 20 with the gate insulating film 29 interposed therebetween, become Lov regions.

In FIG. 2H, the silicide layers 31 become a source region and a drain region. In addition, similarly to FIG. 2F, the low-concentration impurity regions 34a and 34b become Loff regions, and the low-concentration impurity regions 24a and 24b become Lov regions.

When the structure of FIG. 2F is compared with the structure of FIG. 2H, an area of a portion of the silicide layer 31, which is in contact with a part of the semiconductor film including no silicide, is large. Therefore, contact resistance of the silicide layer 31 and the part of the semiconductor film except for the silicide layer 31 becomes low, and parasitic resistance is lower than the structure of FIG. 2H.

On the other hand, when the structure of FIG. 2H is compared with the structure of FIG. 2F, resistance of the source region and the drain region is lowered. In addition, since a step of doping of the impurity ion 32 for forming the high-concentration impurity region is not required, one step can be reduced.

In the present embodiment, a GOLD structure is employed. Therefore, deterioration in the ON current value can be prevented, and high reliability can be realized, as well as a structure of a high ON current can be formed by forming silicide. In addition, a minute TFT can be formed, in which the Lov length is 20 to 200 nm, the Loff length is 30 to 500 nm, and the channel length is 0.1 to 1.0 μm. Therefore, even in the case of an extremely minute TFT, an LDD region suitable for its size can be formed, and a predetermined ON current can be obtained.

In FIGS. 2C to 2F, doping of the impurity ion 32 for forming the high-concentration impurity region is conducted after forming silicide; however, the metal film 30 may be provided to form silicide after doping of the impurity ion 32. In addition, in order to obtain the structure of FIG. 2H, the silicide layer 31 may be formed after doping of the impurity ion 32 by using the sidewalls 28 and the second gate electrode 22 as masks.

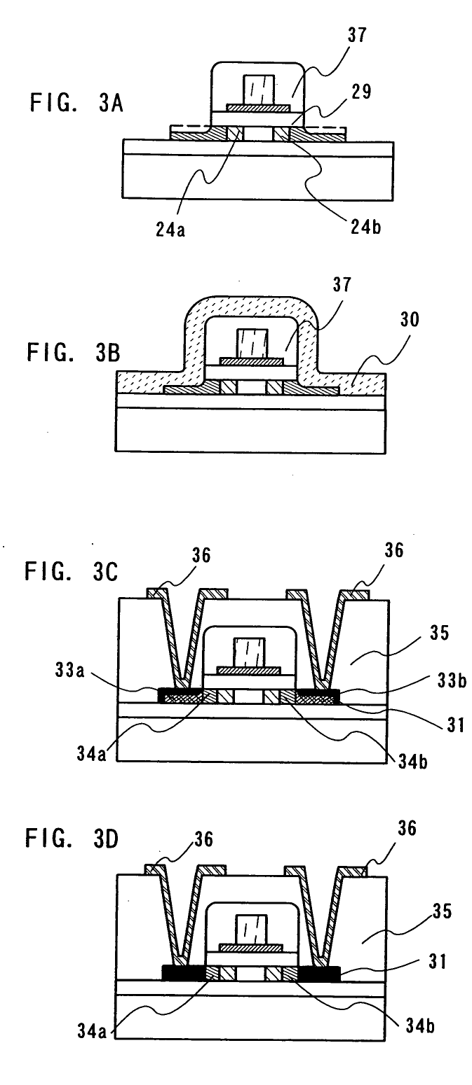

In addition, the metal film 30 is formed after forming the sidewall here; however, the method is not limited thereto. A mask can be used instead of the sidewall, and this method will be described with reference to FIGS. 3A to 3D. After the doping of the impurity ion of FIG. 2A, a mask 37 is formed over a portion that becomes a Loff region (FIG. 3A). An insulating film such as a silicon oxide film or a resist mask can be used to form the mask 37. Thereafter, etching is conducted to remove a part of the gate insulating film and expose a part of the semiconductor film so that a gate insulating film 29 is formed. This exposed part of the semiconductor film becomes a source region and a drain region later.

Next, a metal film 30 is formed, and silicide is formed in the exposed part of the semiconductor film by a heat treatment. Then, silicide is formed as described in FIGS. 2C to 2H, and a structure shown of FIG. 3C or 3D is obtained. In the structures shown here, the mask 37 remains; however, the mask 37 may be removed after forming silicide.

The method of using a mask instead of a sidewall is not limited to the present embodiment and can be applied to Embodiments 2 to 4 that will be described later.

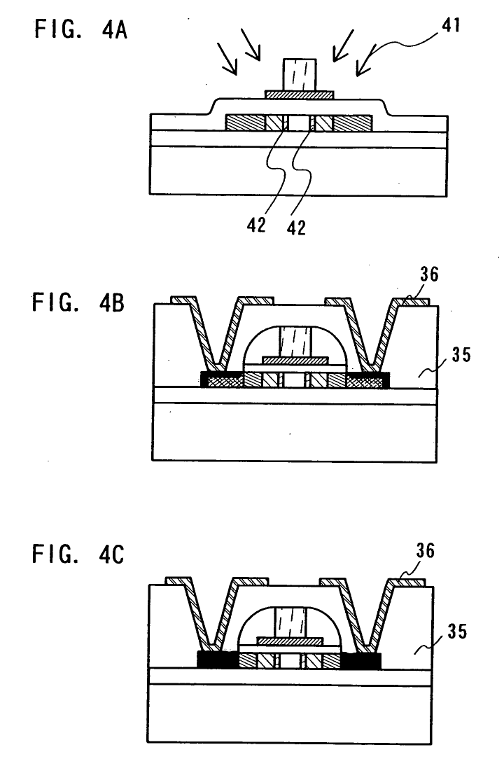

In addition, low-concentration impurity regions 42 can also be formed between the low-concentration impurity regions 34a and 34b which are Lov regions and a channel formation region 26. This structure is referred to as a pocket structure. As shown in FIGS. 4A to 4C, before forming a sidewall 28 or a mask 37, oblique doping of an impurity ion 41 is conducted by using the electrode 20 as a mask. When the oblique doping is conducted before forming the sidewall 28 or the mask 37, oblique doping may be conducted either before or after doping of a low-concentration impurity ion 27. FIGS. 4A to 4C show an example of oblique doping after doping of the low-concentration impurity ion 27. As for a conductivity type of an impurity ion used in doping, a p-type impurity ion is used in the case of an n-channel TFT, whereas an n-type impurity ion is used in the case of a p-type TFT. The low-concentration impurity regions 42 are formed by the oblique doping of the impurity ion 41.

After the impurity regions 42 are formed, a structure of FIG. 4B or 4C is obtained through the steps shown in FIGS. 2B to 2H. In addition, the mask 37 may be used instead of the sidewall through the steps shown in FIGS. 3A to 3D. By employing the pocket structure, short channel effect can be more suppressed.

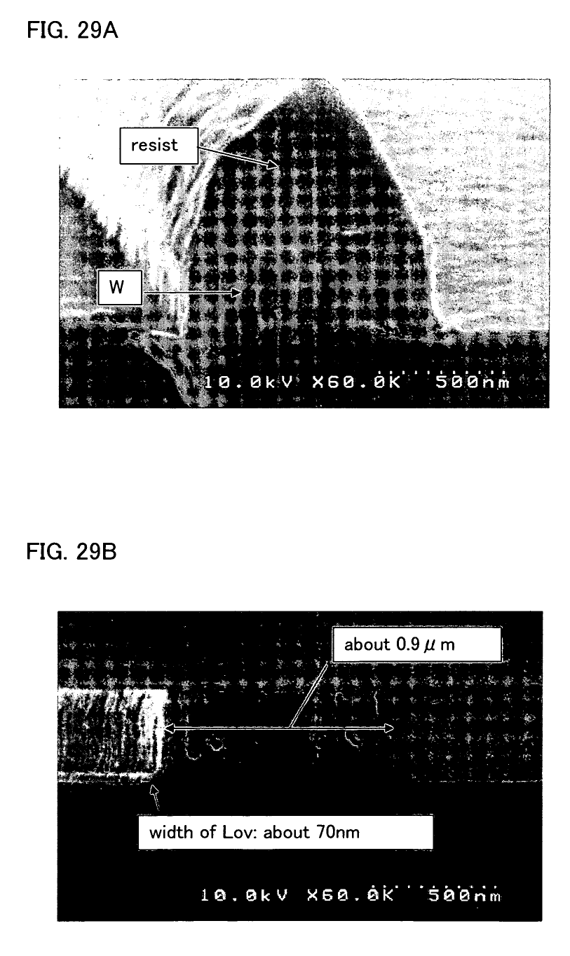

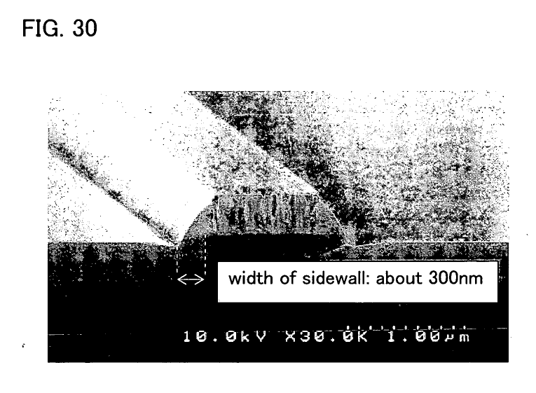

FIGS. 29A and 29B, and 30 each show a SEM photograph of a cross-sectional shape of a hat-shaped gate electrode formed in the present invention.

FIG. 29A shows a state in which a W film is etched by the first etching, and a resist and the W film are shown. FIG. 29B shows a hat-shaped gate electrode after conducting the third etching and removing the resist.

In FIG. 29B, the gate length is approximately 0.9 μm, and the Lov length is approximately 70 nm. In the present invention, the W film has few taper portions as shown in FIG. 29A, and the Lov length is formed by using the resist recess width without using a taper portion; therefore, the Lov length can be extremely short.

In FIG. 29B, a side face of the W film is perpendicular and not side-etched at all. This is because a substrate temperature of a sample stage in the third etching is set lower to be −10° C. or less in the present invention.

FIG. 30 shows a state in which a sidewall is formed in addition to the structure of FIG. 29B. The sidewall width is approximately 300 nm. Therefore, the Loff length is 230 nm (the sidewall width: 300 nm-the Lov length: 70 nm). The sidewall width is a length of one sidewall in a channel length direction in two sidewalls formed on the both side surfaces of the gate electrode. Even when a multi-gate structure is employed and there are two or more sidewalls, the sidewall width is a length of one sidewall in a channel length direction in the plural sidewalls.

As described above, a semiconductor device including the TFT manufactured in the present embodiment can have an LDD region with the extremely short LDD length; therefore, a semiconductor device with high reliability and little deterioration can be realized even in a miniaturized semiconductor device. In addition, by a wiring contact using silicide, a semiconductor device can be realized, in which a desired ON current can be ensured even in a miniaturized TFT.

### Embodiment 2

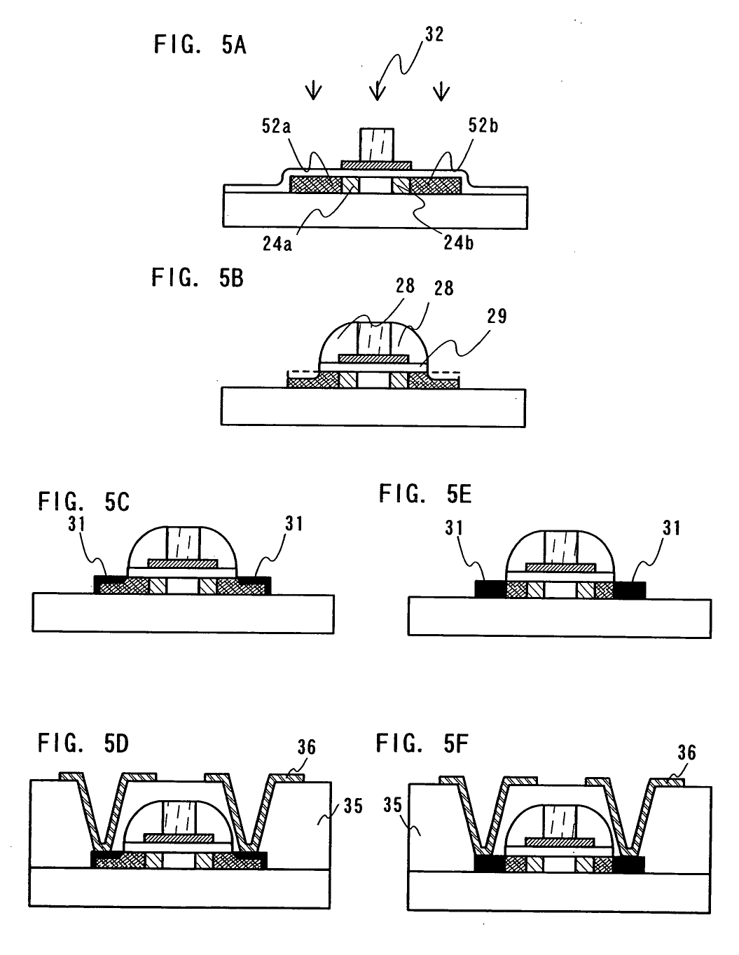

In the present embodiment, a method for manufacturing a semiconductor device having only a Lov region will be described with reference to FIG. 5A to 5F. Further, in the present embodiment, the same reference numerals are used for the same portions as in Embodiment 1, and a detailed explanation is omitted.

In the present embodiment, a TFT is manufactured through the same steps as in Embodiment 1 until the step of FIG. 2A. Subsequently, doping of an impurity ion 32 is conducted by using a first electrode 20 as a mask to form high concentration impurity regions 52a and 52b (FIG. 5A). In addition, doping of the impurity ion 32 for forming the high concentration impurity region and doping of an impurity ion 27 for forming the low concentration impurity region may be conducted in the reverse order; namely, doping of the impurity ion 27 may be conducted after doping of the impurity ion 32, and a state of FIG. 5A is obtained. Alternatively, doping of the impurity ion 27 may be omitted, and only doping of the impurity ion 32 may be conducted. When doping of the impurity ion 32 is conducted to form the high-concentration impurity regions 52a and 52b, low-concentration impurity regions 24a and 24b overlapping with the first gate electrode 20 are also doped with the impurity ion to some extent. By making the use of this phenomenon, the low-concentration impurity regions 24a and 24b can be formed only by doping of the impurity ion 32 without doping of the impurity ion 27.

Then, a sidewall 28 is formed, and a gate insulating film is etched to form a gate insulating film 29 (FIG. 5B). At this time, when an etching selective ratio of the gate insulating film to a semiconductor film is low, the semiconductor film not covered with the sidewall is etched to some extent when the gate insulating film 29 is etched, and a film thickness becomes thin.

After a silicide layer 31 is formed as shown in FIG. 5C or 5E, an interlayer insulating film 35 and a wiring 36 are formed to obtain a structure of FIG. 5D or 5 F.

Although not shown in the drawings here, similarly to Embodiment 1, a mask 37 may be formed to obtain a TFT structure of the present embodiment without forming the sidewall.

Through the above steps, a TFT having the low-concentration impurity regions 24a and 24b as Lov regions can be manufactured. Since the TFT manufactured in the present embodiment has no Loff region, parasitic resistance is lower as compared with the TFT of Embodiment 1, and a high ON current can be realized.

When the pocket structure is employed, a TFT can be formed by the same method as in Embodiment 1.

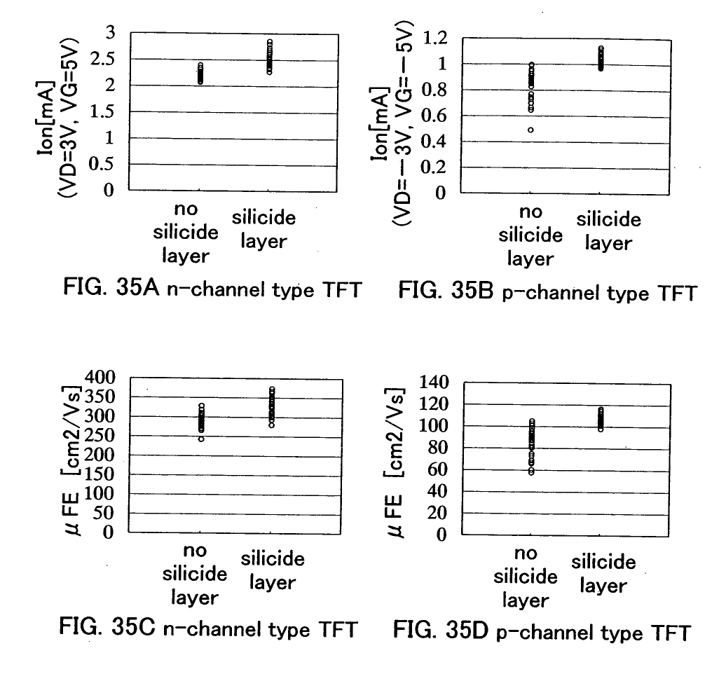

Characteristics of a TFT having the structure of FIG. 5D shown in the present embodiment and a TFT having the structure of FIG. 5D without silicide layer are compared. The results are shown in FIGS. 35A to 35D. It is to be noted that, as for a size of a channel formation region of a TFT, the channel length is 1 μm and the channel width is 8 μm in each TFT.

In FIG. 35A, ON currents in cases of providing a silicide layer and providing no suicide layer are compared as for an n-channel TFT. As the ON current value, the value in the case where a drain voltage is 3V and a gate voltage is 5V is used. In FIG. 35B, ON currents are compared regarding whether a silicide layer is provided or not in a p-channel TFT, and the vertical axis represents the ON current value in the case where a drain voltage is −3V and a gate voltage is −5V. In accordance with FIGS. 35A and 35B, the ON current is higher in the case of providing a silicide layer since it is considered that a silicide layer lowers parasitic resistance of a TFT.

In FIGS. 35C and 35D, the vertical axis represents mobility μ_{FE}, and mobility is compared regarding whether a silicide layer is provided or not. Both in an n-channel TFT and a p-channel TFT, the value of the mobility μ_{FE} is also higher in the case of providing a silicide layer than in the case of providing no silicide layer. Therefore, it is understood that a silicide layer contributes to mobility μ_{FE}.

### Embodiment 3

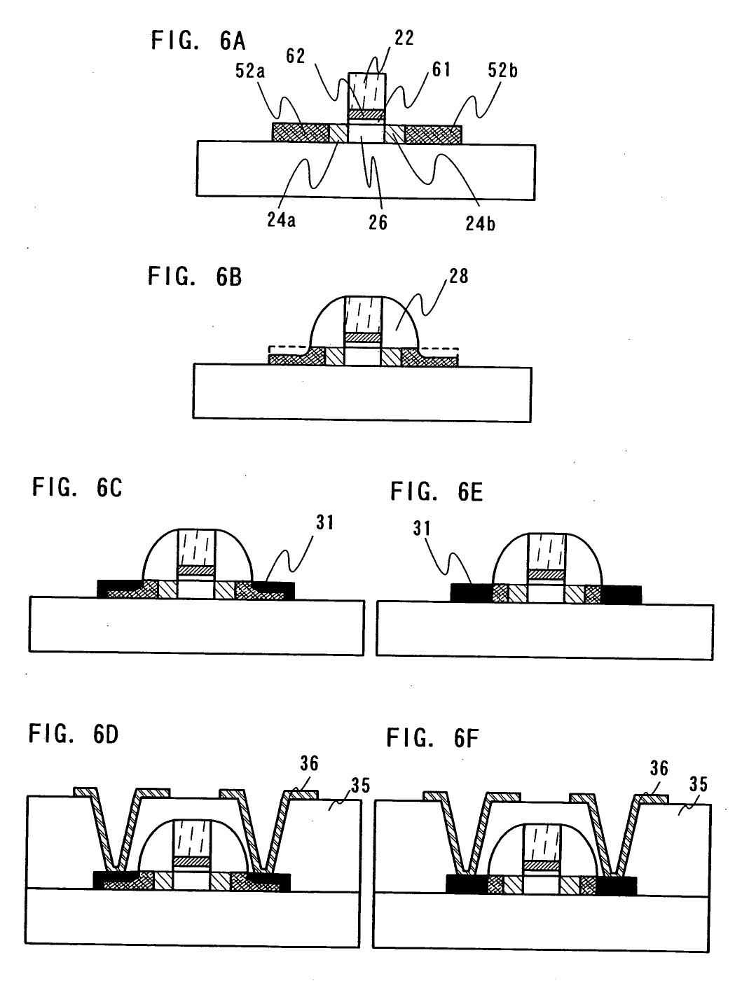

In the present embodiment, a method for manufacturing a semiconductor device having only a Loff region will be described with reference to FIGS. 6A to 6F. Further, in the present embodiment, the same reference numerals are used for the same portions as in Embodiments 1 and 2, and a detailed explanation is omitted.

The same steps as in Embodiment 2 are conducted until FIG. 5A, and low-concentration impurity regions 24a and 24b, high-concentration impurity regions 52a and 52b, and a channel formation region 26 are formed in an island-shaped semiconductor film 13. Then, by using a second gate electrode 22 as a mask, dry etching is conducted to etch a first gate electrode and a gate insulating film 14 so as to have the same width as the gate length of the second gate electrode. By this etching, a third gate electrode 62 and a gate insulating film 61 are formed, and a part of the island-shaped semiconductor film 13 is exposed (FIG. 6A).

Subsequently, an insulating film is deposited over the second gate electrode 22, and dry etching is conducted to form a sidewall 28 (FIG. 6B). The sidewall 28 is formed to cover side surfaces of the second gate electrode 22, the third gate electrode 62, and the gate insulating film 61. When an etching selective ratio of the deposited insulating film to the semiconductor film is low, the semiconductor film is also etched to some extent while forming the sidewall, and a film thickness of the exposed semiconductor film becomes thin.

A metal film composed of a material which reacts with the semiconductor film to form silicide is formed so as to cover the second gate electrode 22 and the exposed island-shaped semiconductor film, and a heat treatment is conducted to form a silicide layer 31 (FIGS. 6C and 6E). Thereafter, the metal film which has not become silicide is removed. Then, an interlayer insulating film and a wiring are formed to complete a TFT (FIGS. 6D and 6F).

Through the above steps, a TFT having the low-concentration impurity regions 24a and 24b as Loff regions can be manufactured. Since the TFT manufactured in the present embodiment does not have a Lov region, parasitic resistance is lower as compared with the TFT of Embodiment 1, and a low OFF current can be achieved.

When the pocket structure is formed between the channel formation region 26 and the low-concentration impurity regions 24a and 24b of the island-shaped semiconductor film, the same method as in Embodiment 1 can be used.

### Embodiment 4

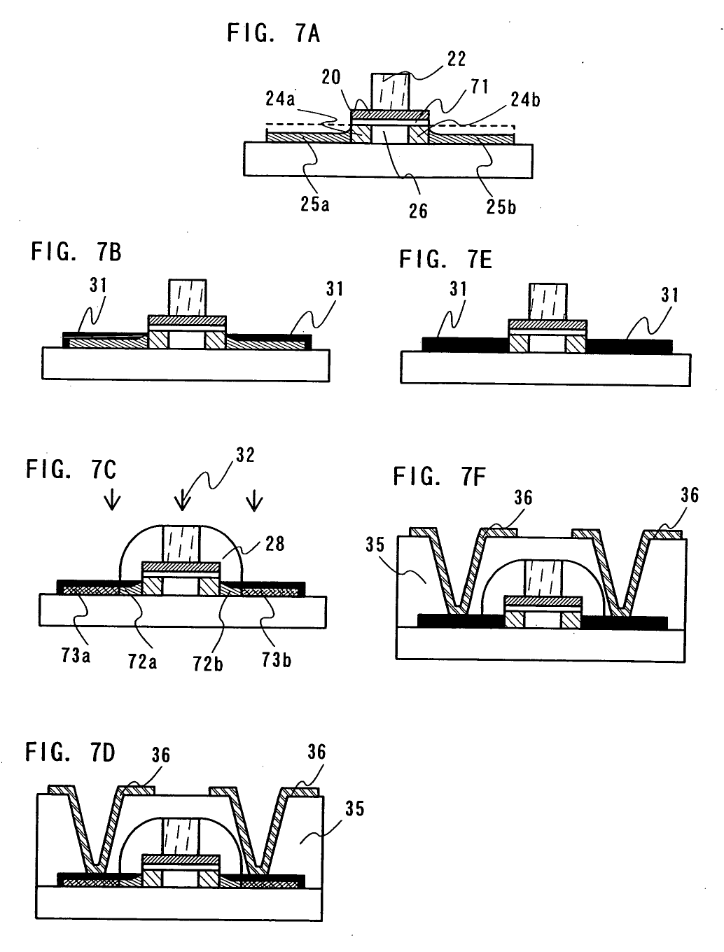

A structure having a Lov region and a Loff region, which is a different structure from Embodiment 1, will be described with reference FIGS. 7A to 7F. In the present embodiment, the same reference numerals are used for the same portions as in Embodiments 1 to 3, and a detailed explanation is omitted.

The same steps as in Embodiment 1 are conducted until FIG. 2A. Then, by using a first gate electrode 20 as a mask, a gate insulating film 14 is etched to form a gate insulating film 71. In addition, a semiconductor film that is exposed from the gate insulating film 71 is etched by using the first gate electrode 20 and the gate insulating film 71 as masks, and a film thickness thereof becomes thin. This etching is conducted to avoid establishing continuity between a silicide layer 31 and the gate electrode in the subsequent step of forming silicide. Therefore, when no continuity is concerned to be established between the silicide layer 31 and the gate electrode, the semiconductor film is not required to be etched. When an etching selective ratio of the gate insulating film to the semiconductor film is low, the semiconductor film is also etched while etching the gate insulating film (FIG. 7A).

A metal film composed of a material which reacts with the semiconductor film to form silicide is formed to be in contact with the first and second gate electrodes and the exposed semiconductor film. The silicide layer 31 is formed by a heat treatment. A structure of FIG. 7B or FIG. 7E is obtained depending on film thicknesses of the semiconductor film and the metal film.

A sidewall 28 is formed to the structure of FIG. 7B. By using the sidewall 28 as a mask, doping of an impurity ion 32 is conducted to form high-concentration impurity regions 73a and 73b which become a source region and a drain region. In addition, low-concentration impurity regions 72a and 72b are also formed (FIG. 7C).

Then, an interlayer insulating film 35 and a wiring 36 are formed. In a structure of FIG. 7D, low-concentration impurity regions 24a and 24b are Lov regions, and the low-concentration impurity regions 72a and 72b are Loff regions. Comparing with the structure of Embodiment 1, the silicide layers 31 are provided also over the low-concentration impurity regions 72a and 72b which are the Loff regions.

In FIG. 7F, the sidewall 28 is further formed to the structure of FIG. 7E, and the interlayer insulating layer 35 and the wiring 36 are formed. The structure of FIG. 7F has the low-concentration impurity regions 24a and 24b as Lov regions and does not have a Loff region. The silicide layers 31 function as a source region and a drain region. Comparing this structure with FIGS. 2H, 5F and 6F in Embodiments 1 to 3, an area of the silicide layer 31 is the largest in the semiconductor film.

In the present embodiment, the gate insulating film 71 is formed after doping of an impurity ion 27. However, the steps can be in the reverse order, and the gate insulating film 71 may be formed before doping of the impurity ion 27.

### Embodiment 5

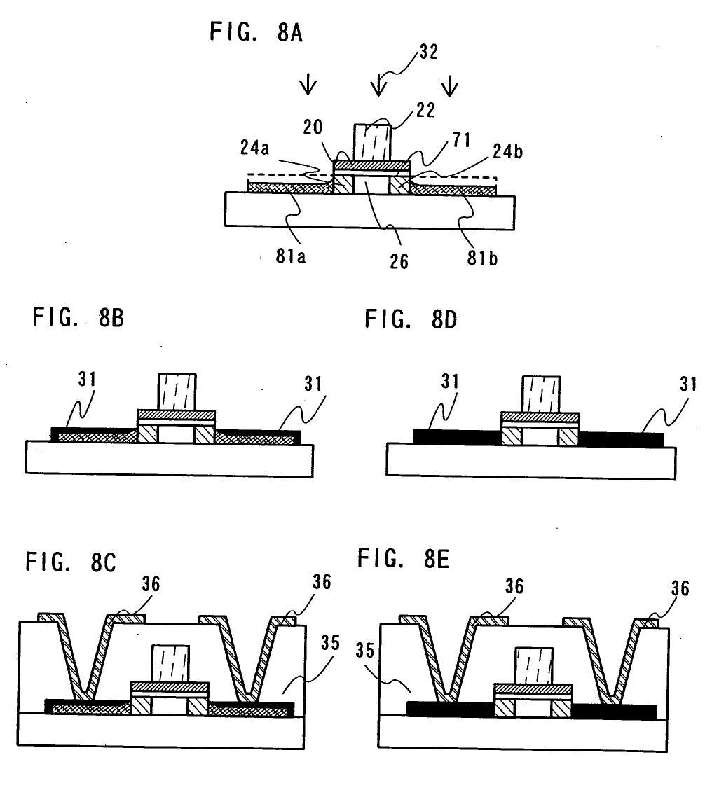

In the present embodiment, a method for manufacturing a semiconductor device having only a Lov region without forming a sidewall will be described with reference to FIGS. 8A to 8E. Further, in the present embodiment, the same reference numerals are used for the same portions as in Embodiments 1 to 4, and a detailed explanation is omitted.

The same steps as in Embodiment 4 are conducted until FIG. 7A, and low-concentration impurity regions 24a, 24b, 25a and 25b, and a channel formation region 26 are formed in an island-shaped semiconductor film 13, further, a gate insulating film 71 is formed over the island-shaped semiconductor film.

Then, doping of an impurity ion 32 is conducted by using a first gate electrode 20 and the gate insulating film 71 as masks to form high-concentration impurity regions 81a and 81b (FIG. 8A). It is to be noted that doping of the impurity ion 32 may be conducted before doping of an impurity ion 27 to obtain a state of FIG. 8A. Alternatively, only doping of the impurity ion 32 may be conducted to obtain a state of FIG. 8A, and doping of the impurity ion 27 may be omitted.

Subsequently, a metal film composed of a material which reacts with the semiconductor film to form silicide is formed to be in contact with the first and the second gate electrodes and the exposed semiconductor film. Then, a heat treatment is conducted to form a silicide layer 31 in a portion in which the exposed island-shaped semiconductor film is in contact with the metal film. A structure of FIG. 8B or FIG. 8D of the silicide layer 31 is obtained depending on film thicknesses of the semiconductor film and the metal film. After forming the silicide layer 31, the metal film which has not become silicide is removed by etching.

Thereafter, as in Embodiment 1, an interlayer insulating film 35 is formed, and wirings 36 which become a source electrode and a drain electrode are formed to complete a TFT (FIGS. 8C and 8E). In FIG. 8E, the silicide layers 31 become a source region and a drain region.

The TFT manufactured in the present embodiment has a Lov region but does not have a Loff region. Therefore, comparing with the structure of Embodiment 1, since there is no Loff region in the structure of the present embodiment, the ON current value can be higher. Moreover, since the structure of the present embodiment does not have a sidewall, a step of forming a sidewall is unnecessary comparing with Embodiment 2.

In the present embodiment, the gate insulating film 71 is formed between doping of the impurity ion 27 and doping of the impurity ion 32. However, the gate insulating film 71 may be formed before doping of the impurity ion 27 or after doping of the impurity ion 32. In the latter case, doping of the impurity ion 32 may be conducted by using the first gate electrode 20 as a mask. In addition, silicide is formed after doping of the impurity ion 32; however, after forming the gate insulating film 71, silicide may also be formed before doping of the impurity ion 32.

When the pocket structure is formed in the present embodiment, the method described in Embodiment 1 may be employed.

### Embodiment 6

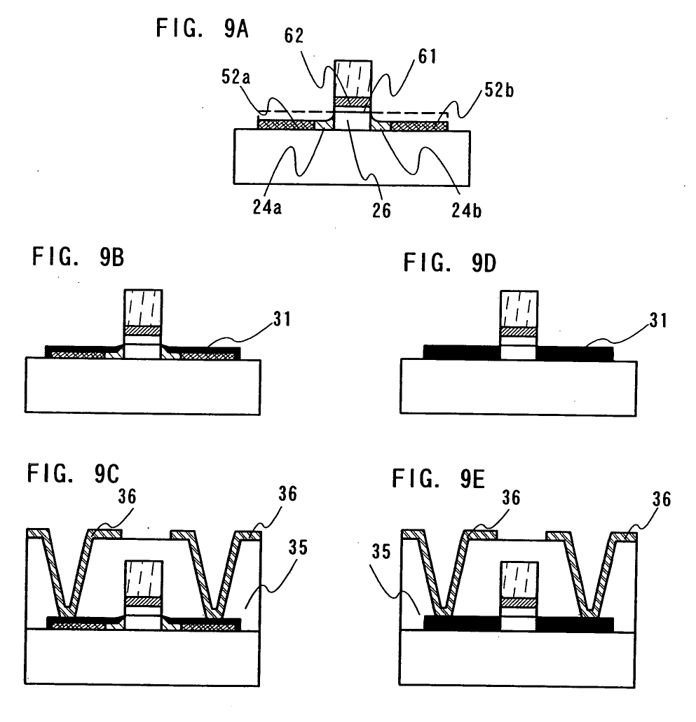

The present embodiment will be described with reference FIGS. 9A to 9E. In the present embodiment, a method for manufacturing a semiconductor device without forming a sidewall in the structure of Embodiment 3 will be described. Further, in the present embodiment, the same reference numerals are used for the same portions as in Embodiments 1 to 5, and a detailed explanation is omitted.

The same steps as in Embodiment 3 are conducted until FIG. 6A, and low-concentration impurity regions 24a, 24b, high-concentration impurity regions 52a and 52b, a channel formation region 26 are formed in an island-shaped semiconductor film 13, further, a third gate electrode 62, and a gate insulating film 61 are formed over the island-shaped semiconductor film 13. After the gate insulating film 61 is formed, an exposed island-shaped semiconductor film 13 is etched by using a second gate electrode as a mask so as to make a film thickness thereof thinner. This etching is conducted to avoid establishing continuity between silicide and the gate electrode in the subsequent step of forming silicide. Therefore, when no continuity is established between silicide and the gate electrode, the film thickness of the exposed island-shaped semiconductor film is not required to be thinner. When an etching selective ratio of a gate insulating film 14 to the semiconductor film is low, the semiconductor film is easily etched while etching the gate insulating film 14 (FIG. 9A).

A metal film composed of a material which reacts with the semiconductor film to form silicide is formed to cover a second gate electrode 22 and the exposed island-shaped semiconductor film, and a heat treatment is conducted to form a silicide layer 31 (FIGS. 9B and 9D). Thereafter, the metal film which has not become silicide is removed. Then, an interlayer insulating film 35 and a wiring 36 are formed to complete a TFT (FIGS. 9C and 9E).

The structure of FIG. 9C is different from the structure of FIG. 6D in Embodiment 3, and the silicide layers 31 are formed also over the low-concentration impurity regions 24a and 24b which are Loff regions. In addition, in FIG. 9E, there is no LDD region, and the silicide layers 31 function as a source region and a drain region.

When the pocket structure is formed between a channel formation region 26 and the low-concentration impurity regions 24a and 24b of the island-shaped semiconductor film, the same method as in Embodiment 1 can be used.

As described in Embodiments 1 to 6, minute TFTs having various structures can be formed by using a minute hat-shaped gate electrode. Accordingly, a plurality of TFTs having different structures can be formed over the same substrate without increasing steps, and an extremely compact semiconductor device can be provided. In addition, since silicide is formed in a contact portion of a wiring and a semiconductor film, contact resistance can be lowered. Therefore, even when parasitic resistance is increased by providing an LDD region in a minute TFT, the parasitic resistance is lowered by lowering the contact resistance; and thus, a desired ON current can be ensured.

### Embodiment 7

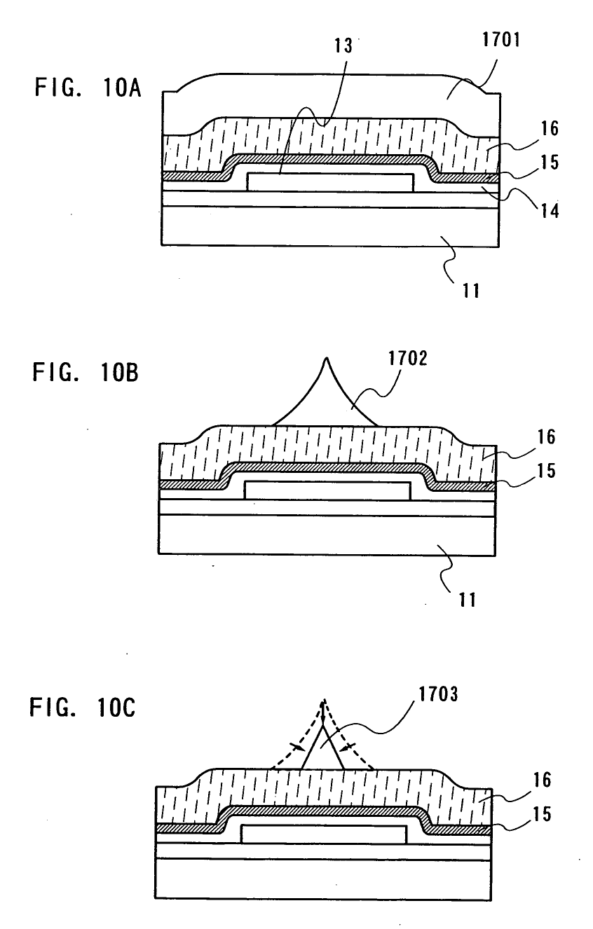

When a TFT forming a semiconductor device according to the present invention is miniaturized, it is important to make the width of a first resist 17 shown in FIG. 1A narrow. It is because the channel length, the Lov length and the Loff length in an LDD region can be short when the first resist 17 is narrow. In the present embodiment, a method for forming the first resist 17, which is for forming the gate electrode, to be minute in the manufacturing steps of a TFT as described in Embodiments 1 to 6 will be described with reference to FIGS. 10A to 10C. Further, in the present embodiment, the same reference numerals are used for the same portions as in Embodiments 1 to 6, and a detailed explanation is omitted.

After a second conductive film 16 is formed, a resist film 1701 is formed over the second conductive film 16 (FIG. 10A). Then, an exposure is conducted to the resist film 1701 to form a pattern 1702 (FIG. 10B). For example, the exposure is conducted by holographic exposure using a holographic mask, or by using a stepper or MPA. In particular, an exposure in submicron size is possible by holographic exposure, thus, it is suitable for forming a minute semiconductor element. The pattern 1702 is a minute pattern having even the width of approximately 1.0 to 1.5 μm, and thus, a shape thereof is likely to become a triangle.

In the present embodiment, slimming process is further conducted to the pattern 1702 with the use of a dry etching apparatus in order to form a more miniaturized TFT. By the slimming process, the width of the pattern 1702 becomes narrower, and a film thickness thereof is reduced. Accordingly, a resist 1703 is formed (FIG. 10C).

Specifically, when the pattern 1702 is formed by using MPA, the pattern 1702 having the width of approximately 1.0 to 1.5 μm is formed. When the width is narrower like the above range, a cross-sectional shape of the pattern 1702 is a triangle.

Then, isotropic dry etching is conducted to the pattern 1702 under the condition that the flow rate of oxygen is 100 sccm, and a temperature of a bottom electrode is −10° C. Plasma is generated by adjusting pressure to be 0.3 Pa and applying power of 2000 W to a coil-shaped electrode. Power is not supplied to a substrate side (sample stage). By this dry etching, the pattern 1702 is recessed to form the resist 1703 having the width of 0.3 to 1.0 μm. A cross-sectional shape of the resist 1703 is an acuter triangle than that of the pattern 1702.

Accordingly, the resist 1703 having the narrow width can be formed. By forming a hat-shaped gate electrode with the use of the resist 1703, a miniaturized TFT can be manufactured, in which the channel length, the Lov length and the Loff length are short. As described above, since an advantageous effect of the present invention can be more efficiently utilized in a miniaturized TFT, it is highly effective to form the resist 1703 having the width of 0.3 to 1.0 μm by the slimming process and form a miniaturized TFT.

### Embodiment 8

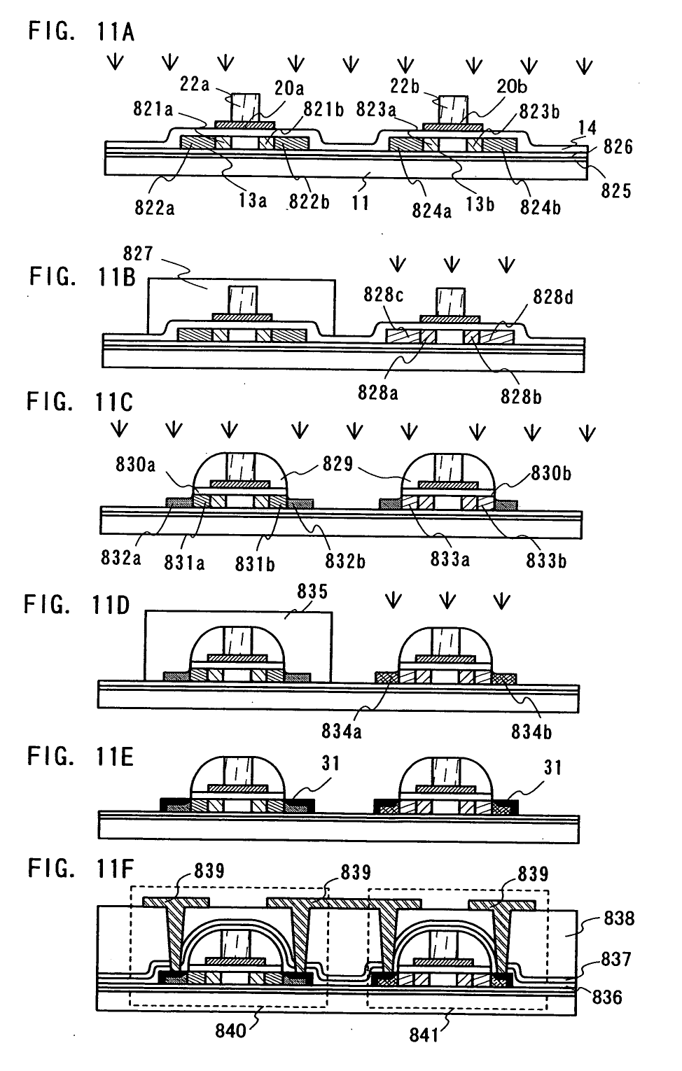

In the present embodiment, a method for forming a p-channel TFT and an n-channel TFT over the same substrate will be described with reference to FIGS. 11A to 11F. It is to be noted that the p-channel TFT and the n-channel TFT have the structure shown in FIG. 2F of Embodiment 1 here. However, the structure is not limited thereto, and the structures of the TFTs in Embodiments 1 to 6 are arbitrarily employed to the p-channel TFT and the n-channel TFT depending on the application. Further, in the present embodiment, the same reference numerals are used for the same portions as in Embodiments 1 to 7, and a detailed explanation is omitted.

After an amorphous semiconductor film is formed over a substrate 11 and channel doping is conducted to the amorphous semiconductor film, the amorphous semiconductor film is crystallized by the method of Embodiment 1 to form a crystalline semiconductor film. Then, etching is conducted to form island-shaped semiconductor films 13a and 13b. The crystalline semiconductor film is a crystalline silicon film here. In addition, as a base film that is in contact with the substrate 11, a stacked layer of a silicon nitride film 825 containing oxygen (SiNxOy) (x>y) and a silicon oxide film 826 containing nitrogen (SiOxNy) (x>y) is used.

Subsequently, a gate insulating film 14 is formed to cover the island-shaped semiconductor films 13a and 13b. As the gate insulating film 14, a silicon oxide film containing nitrogen (SiOxNy) (x>y) is formed by plasma CVD. Then, hat-shaped gate electrodes are formed by the method of Embodiment 1 over the island-shaped semiconductor films 13a and 13b, respectively. Reference numerals 20a and 20b denote first gate electrodes, and 22a and 22b denote second gate electrodes. A resist, to which slimming process described in Embodiment 7 is conducted, may also be used to form a hat-shaped gate electrode.

By using the hat-shaped gate electrodes as masks, the island-shaped semiconductor films 13a and 13b are doped with phosphorus that is an n-type impurity element in a low-concentration by ion doping. Accordingly, in the island-shaped semiconductor film 13a, n-type low-concentration impurity regions 821a and 821b which overlap with the first gate electrode 20a with the gate insulating film interposed therebetween, n-type low-concentration impurity regions 822a and 822b which do not overlap with the first gate electrode 20a, and a channel formation region are formed. Similarly, in the island-shaped semiconductor film 13b, n-type low-concentration impurity regions 823a and 823b which overlap with the first gate electrode 20b with the gate insulating film interposed therebetween, n-type low-concentration impurity regions 824a and 824b which do not overlap with the first gate electrode 20b, and a channel formation region are formed. Doping of phosphorus is conducted to these low-concentration impurity regions so as to include phosphorus in a concentration of 1×10¹⁶ to 5×10¹⁸ atoms/cm³ (FIG. 11A).

Subsequently, a resist mask 827 is formed so as to cover the island-shaped semiconductor film 13a, the first gate electrode 20a, and the second gate electrode 22a. In this condition, by using the first gate electrode 20b and the second gate electrode 22b of the hat-shaped gate electrode as masks, the island-shaped semiconductor film 13b is doped with boron that is a p-type impurity element in a low-concentration by ion doping. Accordingly, in the island-shaped semiconductor film 13b, p-type low-concentration impurity regions 828a and 828b which overlap with the first gate electrode 20b with the gate insulating film interposed therebetween, and p-type low-concentration impurity regions 828c and 828d which do not overlap with the first gate electrode 20b are formed. Doping of boron is conducted to these p-type low-concentration impurity regions so as to include boron in a concentration of 1×10¹⁸ to 1×10¹⁹ atoms/cm³. These p-type low-concentration impurity regions have been already doped with phosphorus in a low-concentration; however, a concentration of boron is higher than that of phosphorus, and n-type conductivity is converted by p-type (FIG. 11B).

Then, a sidewall is formed. A silicon oxide film is formed as an insulating film to cover the island-shaped semiconductor films 13a and 13b, and the hat-shaped gate electrodes. Anisotropic dry etching is conducted to form sidewalls 829. Then, by using the sidewalls 829 as masks, the gate insulating film 14 is etched to form gate insulating films 830a and 830b. Accordingly, both end portions of the island-shaped semiconductor films 13a and 13b are exposed. When an etching selective ratio of the gate insulating film to the exposed part of the semiconductor film is low, the exposed semiconductor film is etched while forming the gate insulating films 830a and 830b, and a film thickness thereof becomes thin as shown in FIG. 11C.

Next, by using the sidewalls 829 and the second gate electrodes 22a and 22b as masks, the n-type low-concentration impurity regions 822a and 822b are doped with phosphorus that is an n-type impurity element in a high-concentration in the self-alignment manner. Accordingly, n-type high-concentration impurity regions 832a and 832b are formed. The n-type high-concentration impurity regions 832a and 832b are doped with phosphorus so as to include phosphorus in a concentration of 1×10²⁰ to 1×10²¹ atoms/cm³. At the same time, n-type low-concentration impurity regions 831a and 831b are formed. Since a part of the p-type low-concentration impurity regions F 828c and 828d is also doped with phosphorus in a high concentration, the exposed part of the island-shaped semiconductor film becomes an n-type high-concentration impurity region. Further, by this doping, p-type low-concentration impurity regions 833a and 833b are formed in the island-shaped semiconductor film 13b.

Subsequently, a resist mask 835 is formed to cover the island-shaped semiconductor film 13a, the first gate electrode 20a, the second gate electrode 22a, and the sidewall. In this condition, by using the second gate electrode 22b and the sidewall 829 as masks, the exposed island-shaped semiconductor film 13b is doped with boron that is a p-type impurity element in a high-concentration in the self-alignment manner. Accordingly, p-type high-concentration impurity regions 834a and 834b are formed. The p-type high-concentration impurity regions have been already doped with phosphorus in a high-concentration and n-type; however, the conductivity is converted by doping of boron and becomes p-type. The p-type high-concentration impurity regions 834a and 834b are doped with boron by ion doping so as to include boron in a concentration of 2×10²⁰ to 5×10²¹ atoms/cm³. Thereafter, the resist mask 835 is removed (FIG. 11D).

Then, a metal film is formed over the entire surface to cover the exposed part of the semiconductor film, and a heat treatment is conducted at a temperature by which the metal film and the semiconductor film react with each other to form a silicide layer 31. The silicide layers 31 are formed over the surface of the p-type and n-type high-concentration impurity regions. In the present embodiment, a nickel film is formed as the metal film, and nickel silicide is formed as the silicide layer 31. Thereafter, the metal film is removed (FIG. 11E).

Then, as a first layer of an interlayer insulating film, a silicon oxide film 836 containing nitrogen is formed to have a film thickness of 50 nm.

Thereafter, activation of the impurity regions which are formed is conducted by a heat treatment. Laser light irradiation, RTA, a heat treatment using a furnace or the like can be used as the heat treatment. However, since silicide is formed and resistance in the source region and the drain region is sufficiently lowered in the present invention, a step of activation may also be omitted.

A silicon nitride film 837 that is a second layer of the interlayer insulating film of 100 nm thick and a silicon oxide film 838 that is a third layer of 600 nm thick are stacked sequentially. Contact holes reaching the silicide layers 31 are formed in the interlayer insulating film. Then, a titanium film of 60 nm, a titanium nitride film of 40 nm, an aluminum film of 500 nm, a titanium film of 60 nm, and a titanium nitride film of 40 nm are stacked sequentially so that the contact holes are filled, and then, this stacked film is etched to form wirings 839 which become a source electrode and a drain electrode (FIG. 11F).

As described above, an n-channel TFT 840 and a p-channel TFT 841 of a LDD structure having both of a Lov region and a Loff region are formed. By this structure, short channel effect and hot carriers can be suppressed even in a minute TFT, and a semiconductor device in which a desired ON current is ensured can be realized.

In the present embodiment, so-called counter doping, in which a semiconductor film of a p-channel TFT is also doped with an n-type impurity element, is conducted; however, the method is not limited thereto. The semiconductor film 13b may also be prevented from doping of phosphorus by covering the p-channel TFT with a resist mask or the like while conducting doping of phosphorus.

### Embodiment 9

In the present embodiment, an example of manufacturing a CPU (Central Processing Unit) by using the present invention will be described. Herein, the CPU is manufactured by using the TFT manufactured in Embodiment 8. Further, in the present embodiment, the same reference numerals are used for the same portions as in Embodiments 1 to 8, and a detailed explanation is omitted.

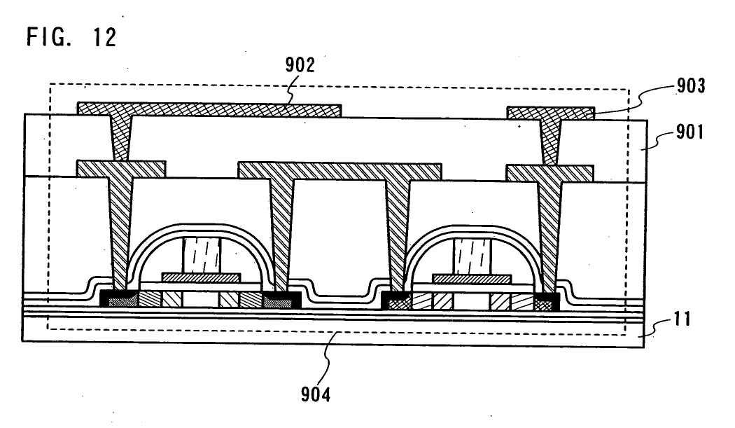

First, as shown in FIG. 12, an insulating layer 901 is formed so as to cover the wirings 839 formed in Embodiment 8. The insulating layer 901 is formed by a single layer or a stacked layer by using an inorganic material or an organic material. The insulating layer 901 is a thin film formed to reduce projections/depressions due to a thin film transistor for the purpose of planarization. Therefore, it is preferably formed by using an organic material.

Then, the insulating layer 901 is etched by photolithography to form contact holes which expose the wirings 839 functioning as a source electrode and a drain electrode. Thereafter, a conductive layer is formed so that the contact holes are filled, and the conductive layer is etched to form conductive layers 902 and 903 functioning as wirings or the like. The conductive layers 902 and 903 are formed by a single layer or a stacked layer composed of an element selected from aluminum (Al), titanium (Ti), silver (Ag) or copper (Cu), or an alloy material or compound material containing the element as its main component. For example, a stacked layer structure of a barrier layer and an aluminum layer; a barrier layer, an aluminum layer and a barrier layer; or the like may be used. The barrier layer corresponds to titanium, titanium nitride, molybdenum, molybdenum nitride or the like.

An element group including a plurality of the n-channel TFTs 840 and a plurality of the p-channel TFTs 841, and a plurality of the conductive layers 902 and 903 functioning as wirings or the like are collectively referred to as a thin film integrated circuit 904. Although not shown in the present steps, a protective layer may be formed by a known method so as to cover the thin film integrated circuit 904. The protective layer may be a layer containing carbon such as DLC (Diamond Like Carbon), a layer containing silicon nitride, a layer containing silicon nitride oxide or the like.

A CPU can be manufactured by forming a plurality of the thin film integrated circuits 904 formed as described above over the same substrate. In the present embodiment, both of the n-channel TFT 840 and the p-channel TFT 841 have the structure described in Embodiment 1.

However, the structure is not limited thereto, and the structures in Embodiments 1 to 6 can be used for each of the n-channel TFT and the p-channel TFT depending on the application. In other words, the minute hat-shaped gate electrode according to the present invention can be used to form a thin film integrated circuit having a different structure from FIG. 12, and a thin film integrated circuit for characteristics of each circuit forming a CPU can be formed.

When the completed CPU is desired to be flexible and more lightweight, a substrate 11 may be separated by a known method, and the CPU may be attached to another lightweight substrate having flexibility.

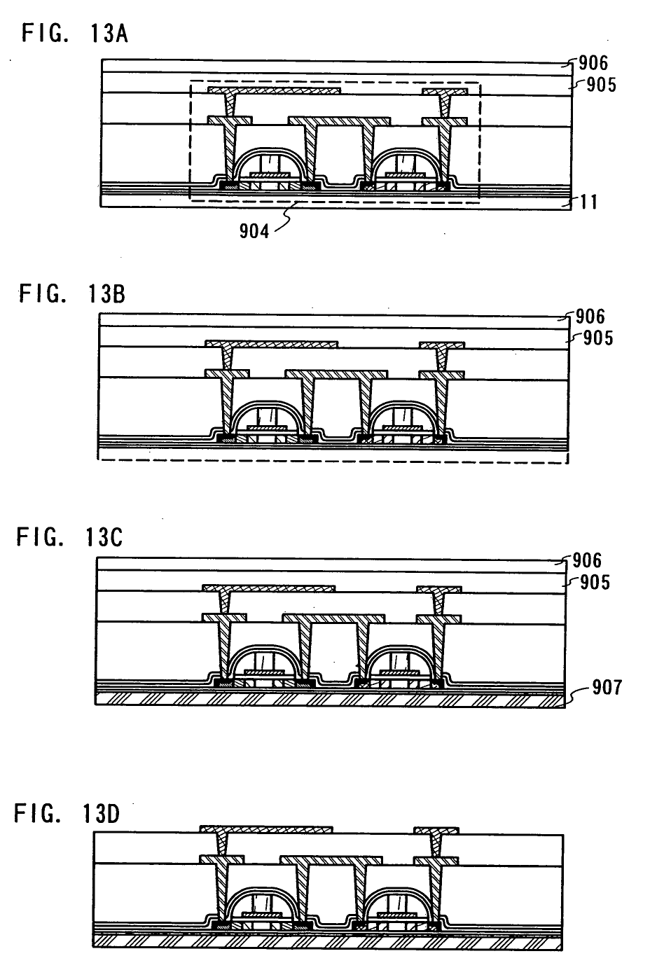

As one method, a method can be used, in which the substrate 11 is physically ground and removed. As shown in FIG. 13A, a substrate 906 is attached to a thin film integrated circuit 904 through a fixing material 905, and the thin film integrated circuit 904 is fixed to the substrate 906. Thereafter, the substrate 11 is ground by mechanical polishing or the like (FIG. 13B). Then, another flexible substrate 907 is attached to the thin film integrated circuit 904 with adhesive or the like (FIG. 13C). Thereafter, the fixing material 905 and the substrate 906 are removed (FIG. 13D). By this method, a lightweight CPU having flexibility can be manufactured.

In addition, a method can also be used, in which a separation layer is provided between the substrate 11 and the semiconductor film in advance, and the separation layer is removed or softened to separate the substrate 11. A method is also given, in which the substrate 11 and the thin film integrated circuit 904 are separated by etching the separation layer as will be described in Embodiment 10. In addition, a method of separating the substrate 11 can also be used, in which the substrate 11 is separated by applying a physical impact to the separation layer, or laser light is absorbed in the separation layer to separate the substrate 11. After the substrate 11 is separated by the above method, a lightweight substrate 907 having flexibility is attached to the thin film integrated circuit 904 as shown in FIG. 13D. A lightweight CPU having flexibility can also be formed by these methods.

Further, a specific configuration of the CPU of the present embodiment will be described with reference to a block diagram.

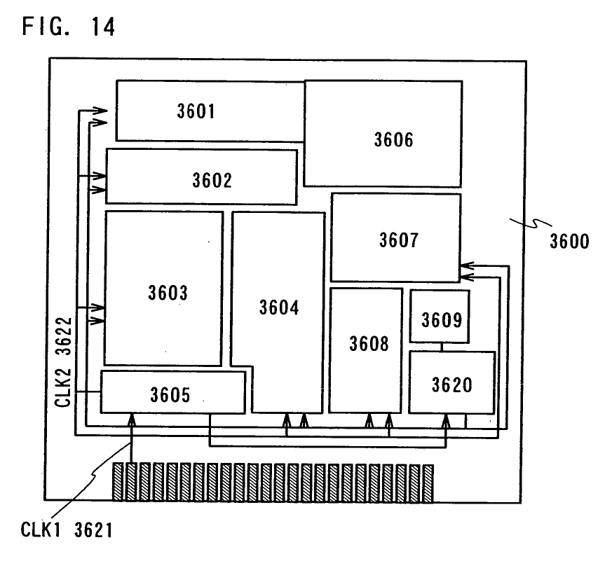

A CPU shown in FIG. 14 mainly includes an arithmetic logic unit (ALU) 3601, an ALU controller 3602, an instruction decoder 3603, an interrupt controller 3604, a timing controller 3605, a register 3606, a register controller 3607, a bus interface (Bus I/F) 3608, a rewritable ROM 3609 and a ROM interface (ROM I/F) 3620, over a substrate 3600. The ROM 3609 and the ROM interface 3620 may be provided over a separate chip as well. These various circuits forming the CPU are formed by a plurality of thin film integrated circuits 904.

Obviously, the CPU shown in FIG. 14 is only an example in which a configuration is simplified, and an actual CPU may have various configurations depending on the application.

An instruction inputted to the CPU through the bus interface 3608 is inputted to the instruction decoder 3603 and decoded therein, and then, inputted to the ALU controller 3602, the interrupt controller 3604, the register controller 3607 and the timing controller 3605.

The ALU controller 3602, the interrupt controller 3604, the register controller 3607 and the timing controller 3605 conduct various controls based on the decoded instruction. Specifically, the ALU controller 3602 generates signals to control the drive of the ALU 3601. While the CPU is executing a program, the interrupt controller 3604 determines an interrupt request from an external input/output device or a peripheral circuit based on its priority or a mask state, and processes the request. The register controller 3607 generates an address of the register 3606, and reads/writes data from/to the register 3606 in accordance with the state of the CPU.

The timing controller 3605 generates signals to control a drive timing of the ALU 3601, the ALU controller 3602, the instruction decoder 3603, the interrupt controller 3604, and the register controller 3607. For example, the timing controller 3605 is provided with an internal clock generator for generating an internal clock signal CLK2 (3622) based on a reference clock signal CLK1 (3621), and supplies the clock signal CLK2 to the various above circuits.

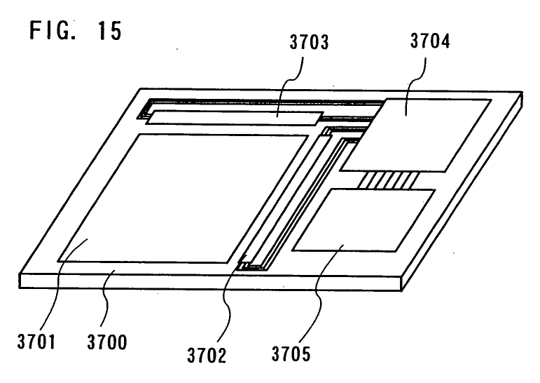

FIG. 15 shows a display device, a so-called system-on-panel in which a pixel portion, a CPU and other circuits are formed over the same substrate. Over a substrate 3700, a pixel portion 3701, a scan line driver circuit 3702 for selecting a pixel included in the pixel portion 3701, and a signal line driver circuit 3703 for supplying a video signal to the selected pixel are provided. A CPU 3704 is connected to other circuits, for example, a control circuit 3705 by wirings which are led from the scan line driver circuit 3702 and the signal line driver circuit 3703. It is to be noted that the control circuit includes an interface. A connecting portion with an FPC terminal is provided at an edge portion of the substrate so as transmit/receive signals to/from external circuits.

As additional circuits, a video signal processing circuit, a power source circuit, a gray scale power source circuit, a video RAM, a memory (DRAM, SRAM, PROM) and the like can be provided over the substrate. Alternatively, these circuits may be formed of an IC chip and mounted over the substrate. Further, the scan line driver circuit 3702 and the signal line driver circuit 3703 are not required to be formed over the same substrate. For example, only the scan line driver circuit 3702 may be formed over the same substrate as the pixel portion 3701 while the signal line driver circuit 3703 may be formed of an IC chip and mounted.

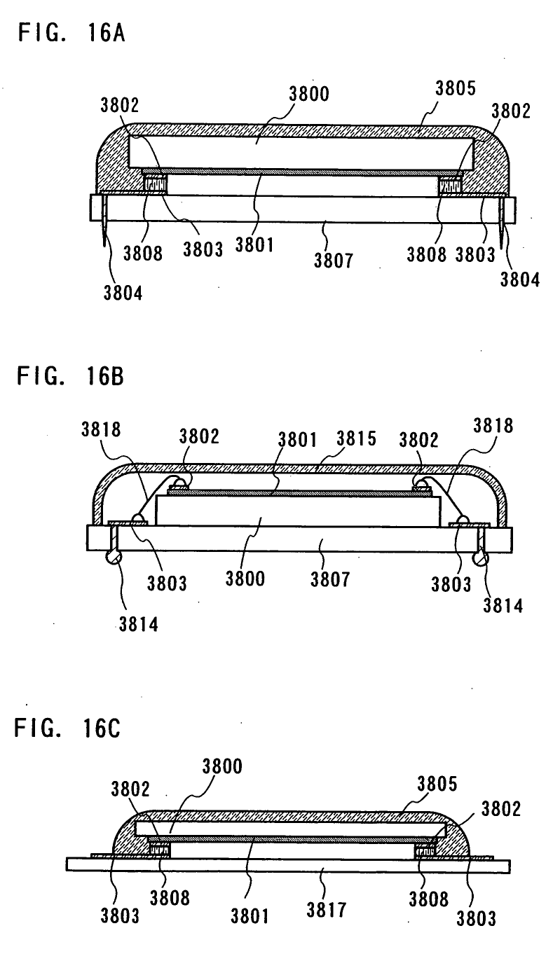

FIGS. 16A to 16C show a mode of a packaged CPU. A substrate 3800 in FIGS. 16A to 16C corresponds to the substrate 11 shown in FIG. 12 or the flexible substrate 907 shown in FIGS. 13C and 13D. A plurality of the thin film integrated circuits 904 are provided over a thin film transistor array 3801.

In FIG. 16A, a CPU is packaged in a face-down position in which the thin film transistor array 3801 having a CPU function formed over the substrate 3800 and electrodes 3802 (a source electrode and a drain electrode, or an electrode formed thereover with an insulating film interposed therebetween) provided over the surface of the CPU are disposed to face the bottom side. In addition, a wiring board provided with wirings 3803 which is formed of copper or an alloy thereof, for example a printed board 3807 is provided. The printed board 3807 is provided with connection terminals (pin) 3804. The electrodes 3802 and the wirings 3803 are connected to each other with anisotropic conductive films 3808 or the like interposed therebetween. Thereafter, the CPU is covered with a resin 3805 such as an epoxy resin from an upper side of the substrate 3800, thereby completing a packaged CPU. Alternatively, the periphery of the substrate may be surrounded with a plastic or the like while keeping a hollow space without covering the CPU with the resin.

In FIG. 16B, unlike FIG. 16A, a CPU is packaged in a face-up position in which the electrodes 3802 formed over the surface of the CPU are provided to face the upper side. The substrate 3800 is fixed over the printed board 3807, and the electrodes 3802 and the wirings 3803 are connected to each other with wires 3818. Such connection with a wire is called wire bonding. The electrodes 3802 and bumps 3814 connected to the wirings 3803 are electrically connected to each other. Thereafter, the CPU is surrounded with a plastic 3815 or the like while keeping a hollow space, thereby completing a packaged CPU.

FIG. 16C shows another mode of a packaged CPU in which the thin film transistor array 3801 having a CPU function is fixed to a flexible substrate, for example an FPC (Flexible Printed Circuit) 3817. A CPU is packaged in a face-down position in which the thin film transistor array 3801 having a CPU function formed over the substrate 3800 is provided so that the electrodes 3802 provided over the surface of the CPU are disposed to face the bottom side. Since the thin film transistor array 3801 is fixed to the FPC 3817 having flexibility, it is preferable to use a highly-flexible plastic as the substrate 3800 so that the strength of the CPU itself is increased. In addition, the FPC 3817 having flexibility is provided with the wirings 3803 formed of copper or an alloy thereof. Then, the electrodes 3802 and the wirings 3803 are connected to each other with the anisotropic conductive films 3808 interposed therebetween. Thereafter, the resin 3805 such as an epoxy resin is formed so as to cover the substrate 3800, thereby completing a packaged CPU.

The CPU packaged in such a manner is protected from external environment so that it can be more easily carried about. In addition, the CPU can be mounted onto a desired position. In particular, when the packaged CPU has flexibility as in FIG. 16C, the mounting position can be determined with high flexibility as well as the strength of the CPU itself is increased. Further, the CPU function can be supplemented by packaging the CPU.

As described above, by using the TFT according to the present invention, a semiconductor device such as a CPU can be manufactured. Since a CPU formed by using the thin film transistor according to the present invention is lightweight and compact, it can be carried about or mounted with fewer loads. In addition, a CPU capable of a high-speed operation and having a longer life can be manufactured.

In addition, the present embodiment can be arbitrarily combined with Embodiments 1 to 8 within a practicable range.

### Embodiment 10

In the present embodiment, a method for manufacturing a wireless chip will be described. Further, in the present embodiment, the same reference numerals are used for the same portions as in Embodiments 1 to 9, and a detailed explanation is omitted.

First, a thin film integrated circuit 904 shown in FIG. 12 is formed. An n-channel TFT 840 and a p-channel TFT 841 have the structure as described in Embodiment 1; however, the structure is not limited thereto, and the structures in Embodiments 1 to 6 can be employed to the n-channel TFT and the p-channel TFT depending on the application.

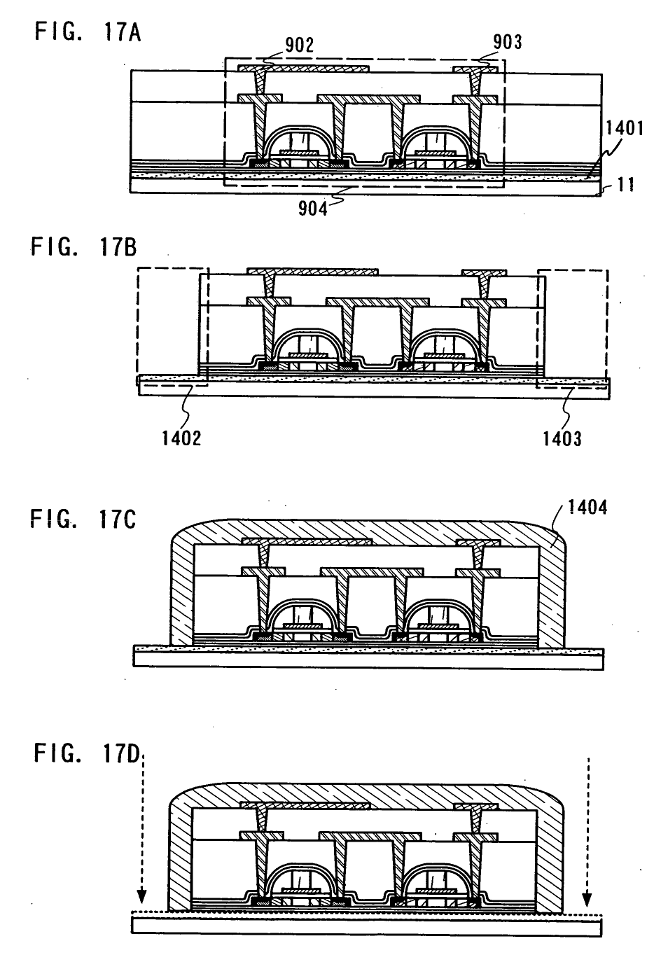

In the present embodiment, in the thin film integrated circuit 904, a separation layer 1401 is formed over one surface of a substrate 11 to separate the substrate 11 in the subsequent step (FIG. 17A). In the present embodiment, the separation layer 1401 is formed over the entire surface of the substrate 11; however, the separation layer can also be provided selectively by photolithography after forming the separation layer over the entire surface of the substrate 11. When the separation layer is selectively provided, there is an advantage that it takes shorter time to remove the separation layer by etching in the subsequent step.

The separation layer 1401 is formed by a known method (e.g., sputtering or plasma CVD) by using a single layer or a stacked layer of an element selected from tungsten (W), molybdenum (Mo), titanium (Ti), tantalum (Ta), niobium (Nb), nickel (Ni), cobalt (Co), zirconium (Zr), zinc (Zn), ruthenium (Ru), rhodium (Rh), lead (Pd), osmium (Os), iridium (Ir) or silicon (Si), or an alloy material or a compound material containing the element as its main component. A layer containing silicon may have any of an amorphous structure, a microcrystalline structure and a polycrystalline structure.

When the separation layer 1401 has a single layer structure, it is preferably formed by using a tungsten layer, a molybdenum layer, or a layer containing a mixture of tungsten and molybdenum. Alternatively, the separation layer 1401 is formed by using a layer containing oxide or oxynitride of tungsten, a layer containing oxide or oxynitride of molybdenum, or a layer containing oxide or oxynitride of a mixture of tungsten and molybdenum. It is to be noted that the mixture of tungsten and molybdenum corresponds to, for example, an alloy of tungsten and molybdenum. Further, oxide of tungsten may be referred to as tungsten oxide.

When the separation layer 1401 has a stacked layer structure, preferably, over the substrate 11, a first layer thereof is formed by using a tungsten layer, a molybdenum layer, or a layer containing a mixture of tungsten and molybdenum, and a second layer thereof is formed by using a layer containing tungsten; molybdenum; or oxide, nitride, oxynitride or nitride oxide of a mixture of tungsten and molybdenum.

When the separation layer 1401 has a stacked layer structure of a layer containing tungsten and a layer containing tungsten oxide, the layer containing tungsten may be formed first and a layer containing silicon oxide may be formed thereover so that a layer containing tungsten oxide can be formed in an interface between the tungsten layer and the silicon oxide layer. This is the same as in the case of forming a layer containing nitride, oxynitride or nitride oxide of tungsten as a second layer. For example, after forming a film containing tungsten as a first layer, a silicon nitride film, a silicon oxide film containing nitrogen or a silicon nitride film containing oxygen may be formed thereover.

Tungsten oxide is represented by WOₓ, where x is 2 to 3. There are cases where x is 2 (WO₂), x is 2.5 (W₂O₅), x is 2.75 (W₄O₁₁), x is 3 (WO₃) and the like. In forming tungsten oxide, the value of x is not specifically limited, and it may be determined based on the etching rate or the like. It is to be noted that a layer containing tungsten oxide (WOₓ, 0<x<3), which is formed by sputtering in an oxygen atmosphere, has the best etching rate. Thus, in order to shorten the manufacturing time, the separation layer is preferably formed by using a layer containing tungsten oxide that is formed by sputtering in an oxygen atmosphere.

The separation layer 1401 may be formed so as to be in contact with the substrate 11. Alternatively, after an insulating layer is formed as a base so as to be in contact with the substrate 11, the separation layer 1401 may be formed so as to be in contact with the insulating layer.

After forming the separation layer 1401, a thin film integrated circuit 904 shown in FIG. 17A is formed through the steps described in Embodiments 8 and 9. Conductive layers 902 and 903 function as antennas of the wireless chip.

Next, although not shown here, a protective layer may be formed to cover the thin film integrated circuit 904 by a known method. The protective layer is a layer containing carbon such as DLC (diamond like carbon), a layer containing silicon nitride, a layer containing silicon nitride oxide, or the like.

Then, a base film, an interlayer insulating film and the like are etched by photolithography so as to expose the separation layer 1401, and openings 1402 and 1403 are formed (FIG. 17B).

Then, an insulating layer 1404 is formed so as to cover the thin film integrated circuit 904 (FIG. 17C). The insulating layer 1404 is formed by using an organic material, preferably an epoxy resin. The insulating layer 1404 is formed to prevent the release of the thin film integrated circuit 904. That is, since the thin film integrated circuit 904 is small and lightweight, it is easily released after removal of the separation layer as it is not tightly attached to the substrate. However, by forming the insulating layer 1404 in the periphery of the thin film integrated circuit 904, the weight of the thin film integrated circuit 904 can be increased, and thus, the release thereof from the substrate 11 can be prevented. The thin film integrated circuit 904 itself is thin and lightweight; however, by forming the insulating layer 1404, the thin film integrated circuit 904 will hardly have a rolled-shape and can have a certain degree of strength. It is to be noted that, in the shown structure, the insulating layer 1404 is formed over the top surface and side surfaces of the thin film integrated circuit 904; however, the present invention is not limited to this structure, and the insulating layer 1404 may be formed only over the top surface of the thin film integrated circuit 904. In addition, in the above description, after forming the openings 1402 and 1403 by etching the base film, L the insulating film or the like, the step of forming the insulating layer 1404 is carried out; however, the present invention is not limited to this order. For example, after the step of forming the insulating layer 1404 over an insulating layer 901, the step of forming the openings may be performed by etching the plural insulating layers. With this order of the steps, the insulating layer 1404 is formed only over the top surface of the thin film integrated circuit 904.

Then, an etching agent is added into the openings 1402 and 1403 to remove the separation layer 1401 (FIG. 17D). As the etching agent, a gas or liquid containing halogen fluoride or a halogen compound is used. For example, chlorine trifluoride (ClF₃) is used as the gas containing halogen fluoride. Thus, the thin film integrated circuit 904 is separated from the substrate 11.

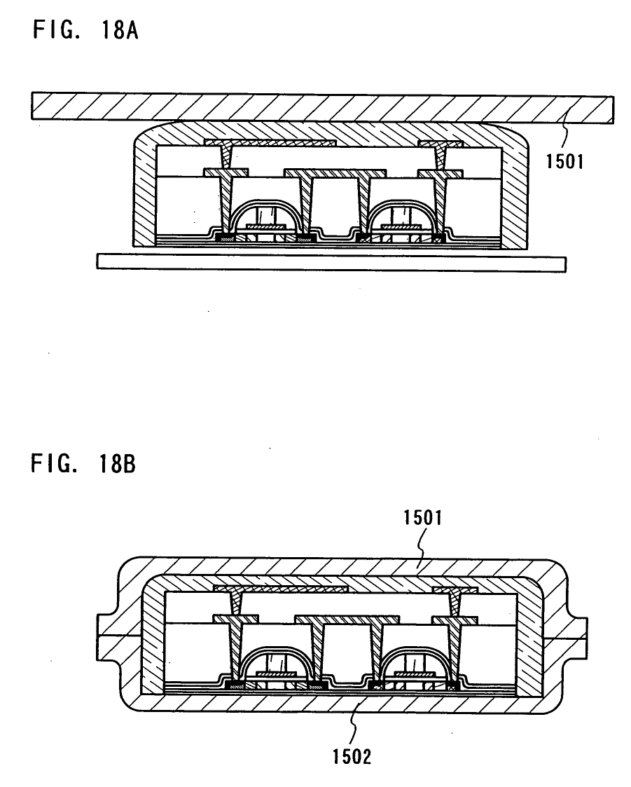

Next, one surface of the thin film integrated circuit 904 is attached to a first base 1501 (FIG. 18A). Alternatively, before removing the separation layer 1401, one surface of the thin film integrated circuit 904 may be attached to the first base 1501. Subsequently, the opposite surface of the thin film integrated circuit 904 is attached to a second base 1502 after removing the thin film integrated circuit 904 from the substrate 11. It is to be noted that the thin film integrated circuit 904 may be attached to the first base 1501 and the second base 1502 through a material having adhesiveness such as adhesive. Alternatively, a magnet or a device for vacuum suction may be used.

Then, the first base 1501 and the second base 1502 are attached to each other so that the thin film integrated circuit 904 is sealed by the first base 1501 and the second base 1502 (FIG. 18B). Thus, a wireless chip is completed, in which the thin film integrated circuit 904 is sealed by the first base 1501 and the second base 1502.

A film composed of a resin material is used as the first base 1501 and the second base 1502. In particular, a film provided with a layer which is dissolved in thermocompression bonding (also referred to as a thermal flexible resin) may be preferably used as the first base 1501 and the second base 1502. Then, either of the first base 1501 or the second base 1502 is dissolved by a heat treatment, and the dissolved base is attached to the other base by applying pressure so that the thin film integrated circuit can be sealed.

The thermal flexible resin used for the first and the second bases preferably has a low softening point. For example, a polyolefin based resin such as polyethylene, polypropylene, or polymethylpentene; a vinyl based copolymer such as vinyl chloride, vinyl acetate, a vinyl chloride-vinyl acetate copolymer, an ethylene-vinyl acetate copolymer, vinylidene chloride, polyvinyl butyral, or polyvinyl alcohol; an acrylic based resin; a polyester based resin; an urethane based resin; a cellulose based resin such as cellulose, cellulose acetate, cellulose acetate butyrate, cellulose acetate propionate, or ethyl cellulose; or a styrene based resin such as polystyrene or a acrylonitrile-styrene copolymer can be used. A film having a single layer or a stacked layer of the thermal flexible resin may be used for the first base 1501 and the second base 1502. A film provided with plural layers of the thermal flexible resin has, for example, a structure in which, over a base including a first thermal flexible resin, an adhesive layer including a second thermal flexible resin having a lower softening point than that of the first thermal flexible resin is provided. A stacked layer structure of two ore more layers may also be employed. In addition, a biodegradable thermal flexible resin may also be used.

In FIGS. 17A to 17D, and 18A and 18B of the present embodiment, the method for manufacturing one wireless chip is described; however, a plurality of wireless chips are manufactured from one substrate in an actual case, and this will be described with reference to 19A to 19D.

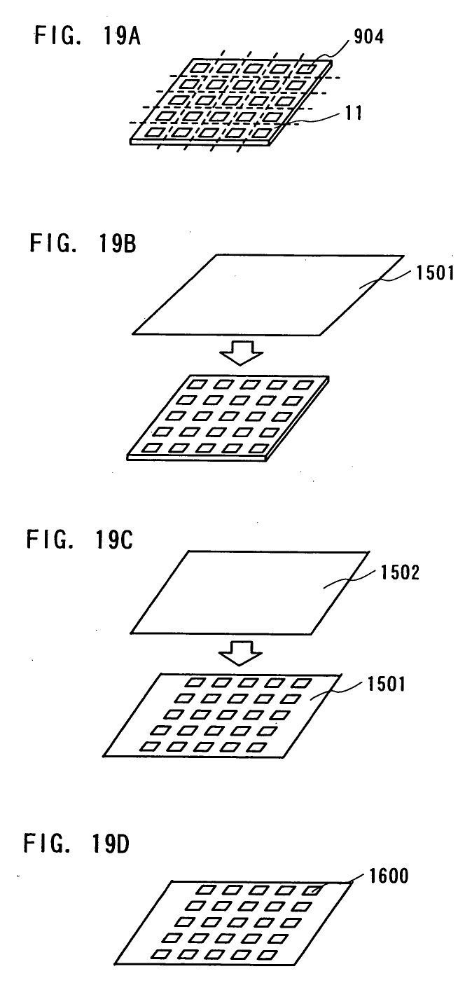

In FIG. 19A, a plurality of thin film integrated circuits 904 are formed in a matrix state over a substrate 11. FIG. 19A is a top view of FIG. 17A. For example, openings 1402 and 1403 are formed along dashed lines between the thin film integrated circuits 904 arranged in a matrix, and a separation layer is etched to separate the thin film integrated circuits 904 from the substrate 11.

Then, as shown in FIG. 18A, a plurality of the separated thin film integrated circuits 904 are attached to a first base 1501 (FIG. 19B). It is to be noted that the first base 1501 and the thin film integrated circuits 904 may be attached to each other, and then, the thin film integrated circuits 904 and the substrate 11 may be separated.

Subsequently, as shown in FIG. 18B, the thin film integrated circuits 904 are attached to a second base 1502 (FIG. 19C). Then, the first base and the second base are attached to each other by thermocompression bonding to seal a plurality of the thin film integrated circuits 904. Thus, a plurality of wireless chips 1600 having the structure of FIG. 18B are completed (FIG. 19D). Then, the wireless chips are separated. An example of the wireless chips which are separated after thermocompression bonding and sealing of the first and the second bases is described here; however, the wireless chips may be separated at the same time as thermocompression bonding.

Through the above steps, a flexible wireless chip is completed. Since the wireless chip manufactured in the present embodiment is extremely minute and flexible, the wireless chip can be disposed to any place without limitation, and can be applied to various objects. In addition, reliability of a TFT forming the wireless chip is high and an ON current is also high; and thus, a wireless chip providing high performance and a longer life can be realized.

A method of etching a separation layer containing tungsten is employed here as a separation method; however, a method other than this separation method may also be used. Another known separation method can also be employed in the present embodiment. For example, a method of separating the substrate 11 by applying a physical impact to the separation layer, or separating the substrate 11 by laser light absorbed in the separation layer can be used. Further, as shown in Embodiment 9, a method of removing the substrate 11 in which the substrate 11 itself is ground without providing the separation layer can also be used.

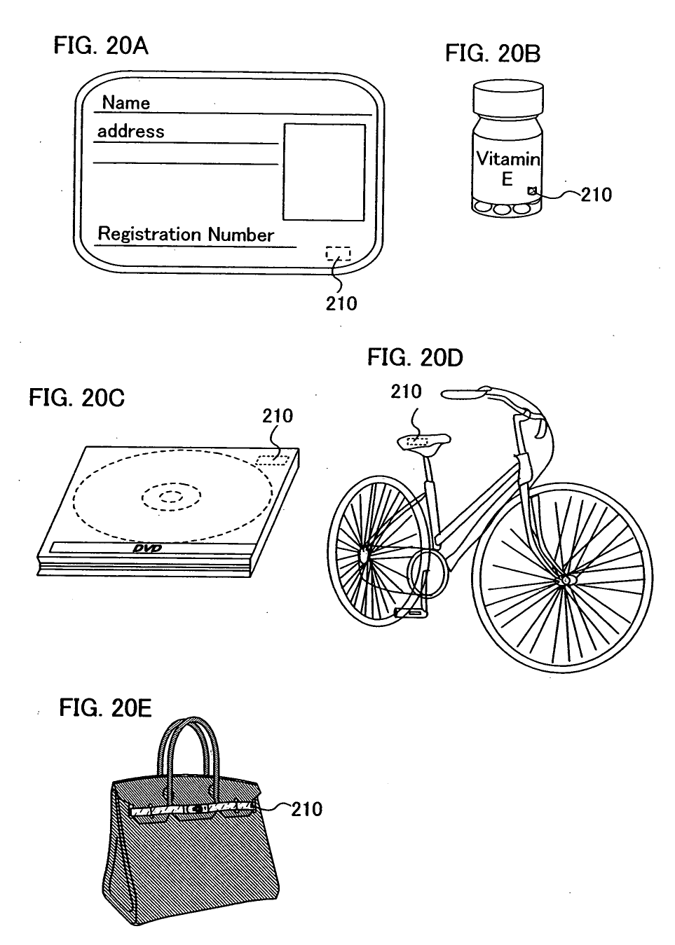

The wireless chip manufactured in the present invention can be used broadly, and may be used by being mounted in objects such as, for example, bills, coins, securities, bearer bonds, certificates (licenses, resident cards and the like, refer to FIG. 20A), containers for wrapping objects (wrapping paper, bottles and the like, refer to FIG. 20B), recording media (DVDs, video tapes and the like, refer to FIG. 20C), vehicles (bicycles and the like, refer to FIG. 20D), personal belongings (bags, glasses and the like, refer to FIG. 20E), foods, clothes, livingware, and electronic devices. The electronic devices include a liquid crystal display device, an EL display device, a television unit (also simply referred to as a TV, a TV receiver or a television receiver), a cellular phone, and the like. Reference numeral 210 denotes a wireless chip manufactured in the present embodiment.

The wireless chip is attached to the surface of the objects, or incorporated to be fixed in the objects. For example, it may be incorporated in paper of a book, or an organic resin of a package to be fixed in each object. By providing the wireless chip in bills, coins, securities, bearer bonds, certificates, and the like, forgery thereof can be prevented. Further, by providing the wireless chip in containers for wrapping objects, recording media, personal belongings, foods, clothes, livingware, electronic devices, and the like, an inspection system or a system in a rental shop can be more effective. By providing the wireless chip in vehicles, forgery or theft can be prevented.

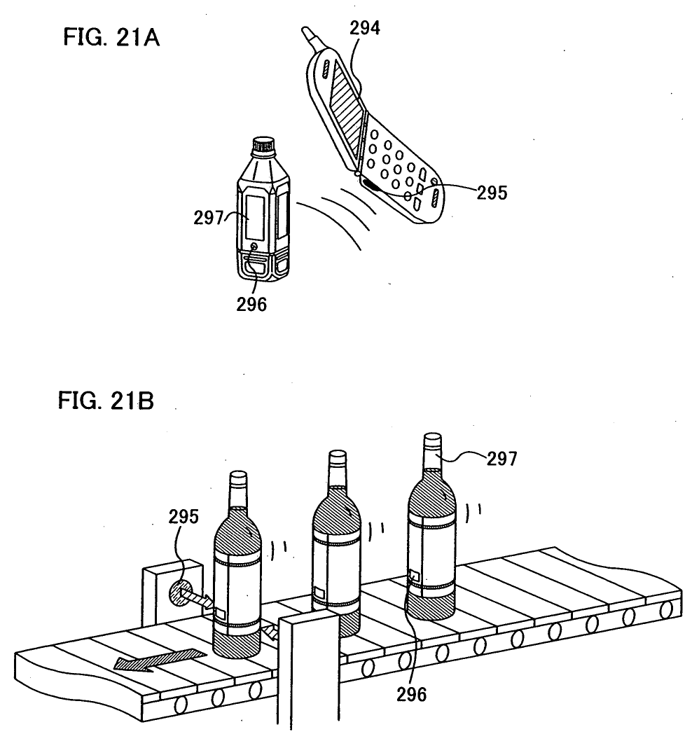

In addition, by applying the wireless chip to merchandise management or circulation system, a higher function of the system can be achieved. For example, there is a case where a reader/writer 295 is provided on the side face of a portable terminal including a display portion 294, and a wireless chip 296 is provided on the side face of a product 297 as shown in FIG. 21A. In this case, when the wireless chip 296 is put close to the reader/writer 295, data on the raw material or place of origin, a circulation record and the like of the product 297 is displayed on the display portion 294. Alternatively, there is a case where a reader/writer 295 is provided beside a belt conveyer, and products 297 provided with the wireless chip 296 are passed on the belt (FIG. 21B). In this case, inspection of the products 297 can be carried out easily.

### Embodiment 11

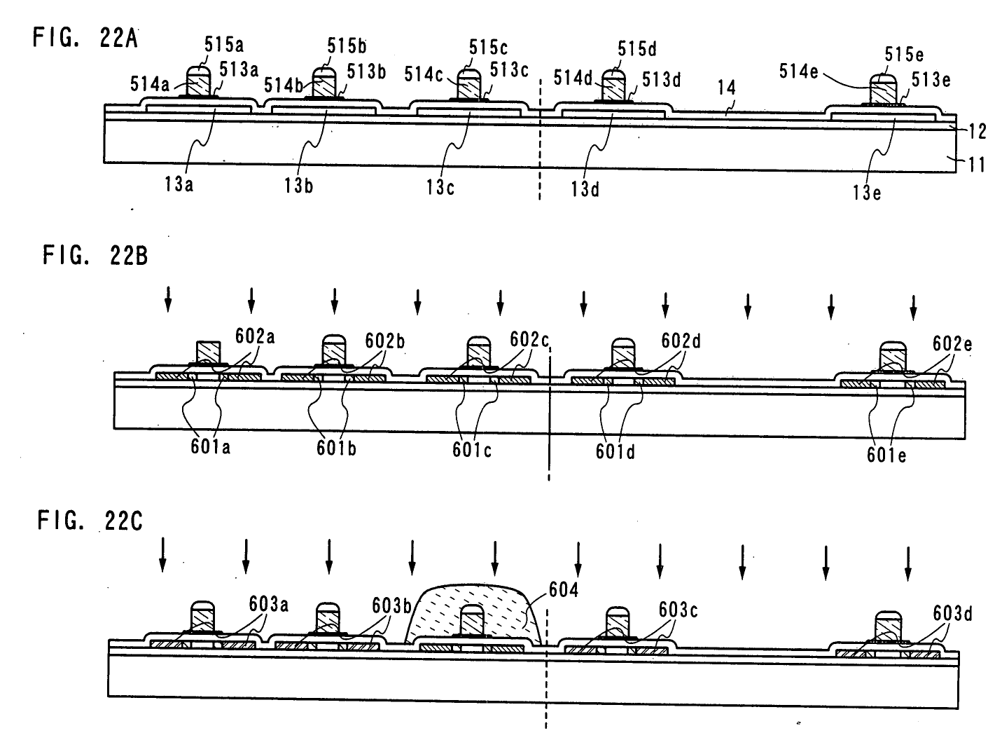

In the present embodiment, a method for manufacturing a display device by using TFTs of various structures described in Embodiments 1 to 6 will be described with reference to FIGS. 22A to 22C, 23A to 23C, 24A to 24C, and 25A and 25B. The method for manufacturing a display device that will be described in the present embodiment is a method for manufacturing TFTs of a pixel portion and its peripheral driver circuit portion concurrently. Further, in the present embodiment, the same reference numerals are used for the same portions as in Embodiments 1 to 10, and a detailed explanation is omitted.

First, by the method of Embodiment 1, a plurality of minute hat-shaped gate electrodes, in which a difference of the gate length of a first gate electrode and the gate length of a second gate electrode is 20 to 200 nm, according to the present invention are formed (FIG. 22A). In other words, first gate electrodes 513a to 513e, and second gate electrodes 514a to 514e are formed. Reference numerals 515a to 515e denote resists, and 13a to 13e denote island-shaped semiconductor films. A resist obtained by slimming process described in Embodiment 7 may be used to form a hat-shaped gate electrode.

Then, by using the resists 515a to 515e and the second gate electrodes 514a to 514e as masks, an n-type impurity element (phosphorus in the present embodiment) is added in a self-alignment manner. It is preferable that low-concentration impurity regions 601a to 601e which overlap with the first gate electrodes with a gate insulating film interposed therebetween and low-concentration impurity regions 602a to 602e which do not overlap with the first gate electrodes are doped with phosphorus in a concentration of 1×10¹⁶ to 5×10¹⁸ atoms/cm³ (typically, 3×10¹⁷ to 3×10¹⁸ atoms/cm³). However, since the low-concentration impurity regions 601a to 601e are doped through the first gate electrodes, the concentration of the impurity element is lower than that contained in the low-concentration impurity regions 602a to 602e (FIG. 22B).

Then, doping is conducted in a high-concentration as shown in FIG. 22C. Before that, a resist 604 is formed so that the low-concentration impurity regions 601c and 602c are not doped with an impurity element. The second doping is conducted in a self-alignment manner by using the resist 604; the resists 515a, 515b, 515d, and 515e; the second gate electrodes 514a, 514b, 514d, and 514e; and the first gate electrodes 513a, 513b, 513d, and 513e as masks to add an n-type impurity element (phosphorus in the present embodiment) selectively to the low-concentration impurity regions. It is preferable that high-concentration impurity regions 603a to 603d thus formed are doped with phosphorus to include phosphorus in a concentration of 1×10²⁰ to 5×10²¹ atoms/cm³.

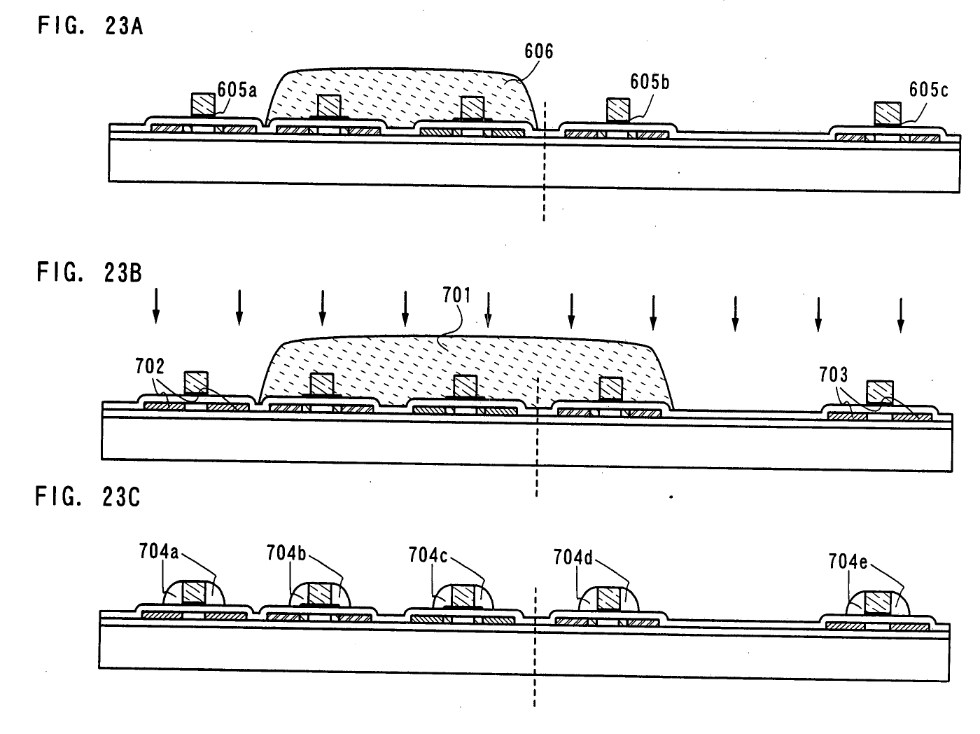

Then, a resist 606 is formed as shown in FIG. 23A after removing the resist 604 and the resists 515a to 515e. Then, the first gate electrodes 513a, 513d, and 513e are partially etched by using the second gate electrodes 514a, 514d and 514e as masks to obtain third gate electrodes 605a, 605b, and 605c having the same gate length as the second gate electrodes, respectively. Thereafter, the resist 606 is removed.

When the resist 606 is formed without removing the resists 515a to 515e to form the third gate electrodes 605a, 605b and 605c, Cl₂ is used as an etching gas, pressure in a chamber is set to be 0.67 Pa by an exhaust system, and power of 2000 W is applied to a coil-shaped electrode to generate plasma. Power of 50 W is applied to a substrate side (sample stage).

Subsequently, a resist 701 is formed (FIG. 23B). The high-concentration impurity regions 603a and 603d, and the low-concentration impurity regions 601a and 601e, which have been the n-type impurity regions, are doped with a p-type impurity element (boron in the present embodiment). Specifically, doping is conducted to the above regions to include the p-type impurity element in a concentration of 3×10²⁰ to 3×10²¹ atoms/cm³ by ion doping using diborane (B₂H₆). Therefore, impurity regions 702 and 703 containing boron in a high concentration are formed. Accordingly, the impurity regions 702 and 703 each function as a source region and a drain region of a p-channel TFT.

Then, the resist 701 is removed as shown in FIG. 23C. Thereafter, sidewalls 704a to 704e are formed on both sides of the third gate electrodes 605a to 605c, the first gate electrodes 513b and 513c, and the second gate electrodes 514a to 514e. The sidewalls 704a to 704e are formed by being etched back after forming an insulating film as shown in Embodiment 1.

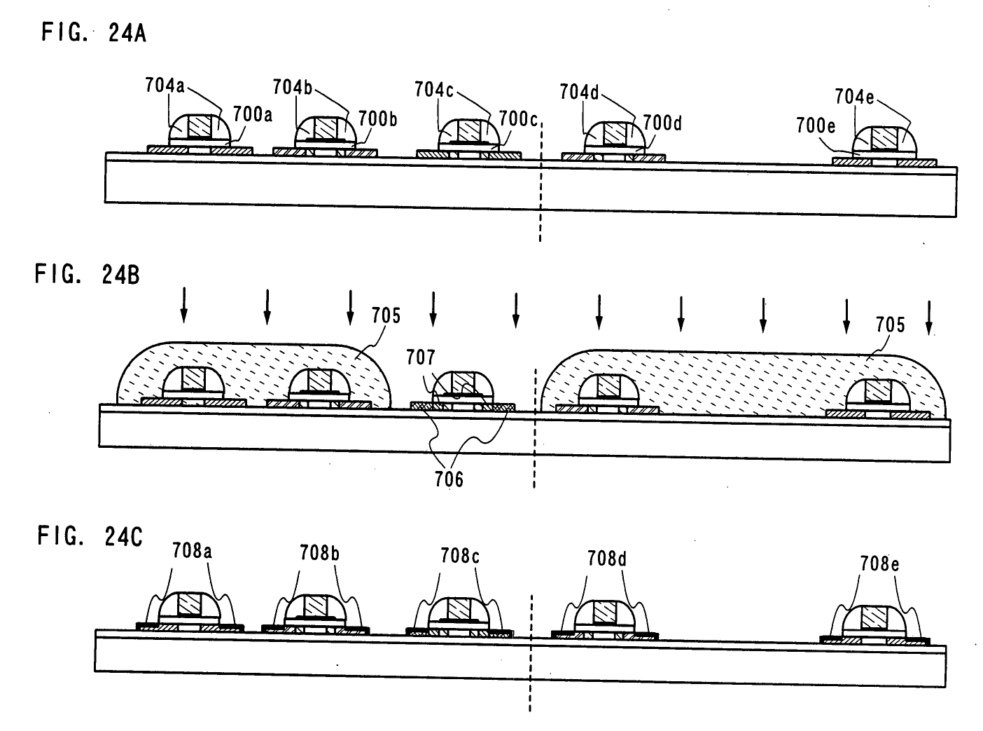

Then, a gate insulating film 14 is etched by dry etching using the sidewalls 704a to 704e as masks (FIG. 24A). By this etching, gate insulating films 700a to 700e are formed.

Then, resists 705 are formed, and doping is conducted. By this doping, an impurity element is added partially into the n-type low-concentration impurity regions 602c by using the resists 705, the sidewalls 704c, and the second gate electrode 514c as masks. Phosphorus (PH₃) is used as the impurity element, and an n-type high-concentration impurity element (phosphorus in the present embodiment) is added by ion doping in a concentration of 1×10²⁰ to 5×10²¹ atoms/cm³ (typically, 2×10²⁰ to 5×10²¹ atoms/cm³); thus, impurity regions 706 containing phosphorus in a high concentration are formed. At the same time, low-concentration impurity regions 707 to be a Loff region are formed. The low-concentration impurity regions 601c become Lov regions (FIG. 24B).

Next, silicide layers 708a to 708e are formed as shown in FIG. 24C. A nickel film is formed to be in contact with an exposed semiconductor film, after removing the resist 705. Then, a heat treatment is conducted at a temperature by which silicide can be formed to form the silicide layers.

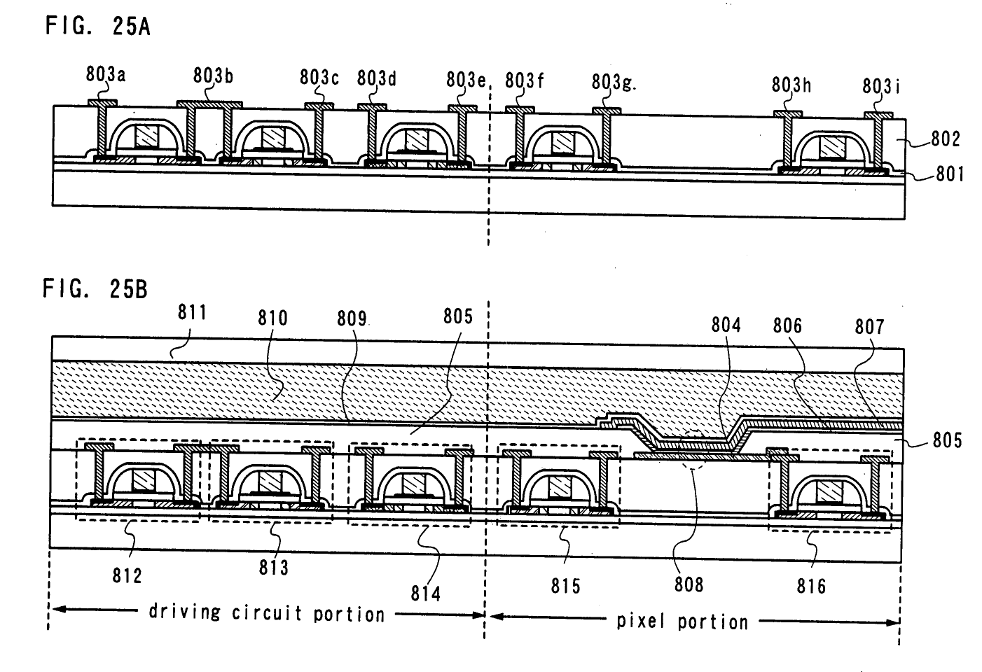

Then, a passivation film 801 is formed to have a thickness of 50 to 500 nm (typically, 200 to 300 nm) as a protective film. This can be substituted with a silicon oxide film, a silicon nitride film, a silicon nitride oxide film, or a stacked layer of these films. Blocking effect for preventing penetration of various ionic impurities, which includes oxygen or moisture within an atmosphere can be obtained by providing the passivation film 801 (FIG. 25A).

Then, an interlayer insulating film 802 is formed to have a film thickness of 1.6 μm over the passivation film 801. The interlayer insulating film 802 can be formed by using the following films that are applied by an SOG (Spin On Glass) method or a spin coating method: an organic resin film such as polyimide, polyamide, BCB (benzocyclobutene), acrylic, or siloxane; an inorganic interlayer insulating film (an insulating film containing silicon such as silicon nitride or silicon oxide); or a film such as formed from a low-k (low dielectric constant) material. Siloxane is composed of a skeleton structure formed by the bond of silicon (Si) and oxygen (O), in which an organic group at least containing hydrogen (such as an alkyl group or aromatic hydrocarbon) is included as a substituent, where a fluoro group or an organic group at least containing hydrogen may be used alternatively as the substituent. The interlayer insulating film 802 is preferably a film superior in terms of planarity because the interlayer insulating film 802 relieves unevenness caused by TFTs formed over the glass substrate and thus has great significance of planarity. Thereafter, a passivation film may be further formed over the interlayer insulating film.

Then, contact holes are formed in the passivation film 801 and the interlayer insulating film 802, and then source and drain wirings 803a to 803i are formed. In the present embodiment, the source and drain wirings each have a three-layer structure of a titanium film, a first aluminum film, and a second aluminum film containing carbon and a metal element or a three-layer structure of a molybdenum film, a first aluminum film, and a second aluminum film containing carbon and a metal element. The first aluminum film may be the one mixed with other metal element. Titanium, molybdenum, or nickel is given as an example of the metal element contained in the second aluminum film. Needless to say, other metal may be used for the source and drain wirings instead of the above metals.

Subsequently, a pixel electrode 804 is formed to be in contact with the drain wiring 803h (FIG. 25B). The pixel electrode 804 is formed by etching a transparent conductive film. The transparent conductive film can be a compound of indium oxide and tin oxide, a compound of indium oxide and zinc oxide, zinc oxide, tin oxide, or indium oxide.

When the pixel electrode 804 is formed by using a transparent conductive film and the drain wiring is formed by using an aluminum film, aluminum oxide is formed in the interface. Since oxide has high resistance, high resistance is generated between the pixel electrode and the drain wiring. However, in the present embodiment, the pixel electrode is connected to the second aluminum film; therefore, oxide is not formed. This is because the metal element contained in the second aluminum film suppresses oxide to be formed. Accordingly, the resistance in the interface between the drain wiring and the pixel electrode can be kept low.

After forming the pixel electrode, a partition wall 805 is formed by using a resin material. The partition wall 805 is formed by etching an acrylic film or a polyimide film of 1 to 2 μm thick so that a part of the pixel electrode 804 is exposed. It is to be noted that a black film to serve as a light-shielding film (not shown) may be provided appropriately below the partition wall 805.

Then, an EL layer 806 and an electrode (MgAg electrode) 807 are formed continuously by a vacuum vapor deposition method without being exposed to an atmosphere. It is preferable to form the EL layer 806 to have a thickness of 100 nm to 1 μm and the electrode 807 to have a thickness of 180 to 300 nm (typically, 200 to 250 nm). The EL layer may be formed by an ink-jet method, a screen-printing method, or the like as well.

In this step, an EL layer and a cathode are formed in order in each pixel corresponding to red, green, and blue. It is necessary to form the EL layer individually for each color without using a photolithography technique because the EL layer has low resistance to a solution. Therefore, it is preferable to cover pixels other than the predetermined pixels with a metal mask to form an EL layer and a cathode selectively only in necessary portions. At least one of each color is colored with a triplet compound. Since the triplet compound has higher luminance than a singlet compound, it is preferable that the triplet compound is used to form a pixel corresponding to red that looks dark, and the singlet compound is used to form other pixels.

In other words, a mask for covering all pixels other than the pixels corresponding to red is set, and an EL layer for red emission and an electrode are selectively formed with the use of the mask. Next, a mask for covering all pixels other than the pixels corresponding to green is set, and an EL layer for green emission and an electrode are selectively formed with the use of the mask. Then, a mask for covering all pixels other than the pixels corresponding to blue is set, and an EL layer for blue emission and an electrode are selectively formed with the use of the mask. It is to be noted that different masks are used for each color in this description; however, the same mask may be used plural times. In addition, it is preferable to maintain vacuum until the EL layers and the electrodes are formed in all the pixels.

The EL layer 806 may be formed by using a known material. It is preferable to use an organic material as a known material in consideration of a drive voltage. For example, an EL layer having a four-layer structure of a hole-injecting layer, a hole-transporting layer, a light-emitting layer, and an electron-injecting layer is preferably formed. A film in which molybdenum oxide and α-NPD are mixed (OMOx film) may also be used for the EL layer. Alternatively, a hybrid layer in which an organic material and an inorganic material are combined may also be used for the EL layer. In the case of using an organic material for the EL layer, each of a low molecular weight material, a middle molecular weight material, and a high molecular weight material can be used. In addition, the present embodiment shows the example of using the MgAg electrode as a cathode of an EL element; however, other known material may also be used.

Upon forming up to the electrode 807, a light-emitting element 808 is completed. Thereafter, a protective film 809 is provided so as to cover the light-emitting element 808 completely. The protective film 809 can be formed by using an insulating film including a carbon film, a silicon nitride film, or a silicon nitride oxide film. Such insulating films can be used as a single layer or a stacked layer.

Further, a sealing material 810 is provided to cover the protective film 809, and a cover member 811 is attached thereto. The sealing material 810 is an ultraviolet ray curing resin, which preferably contains inside a hygroscopic substance or an antioxidant substance. Furthermore, in the present embodiment, a glass substrate, a quartz substrate, or a plastic substrate can be used for the cover member 811. Although not shown, a polarizing plate may be provided between the sealing material 810 and the cover member 811. By providing the polarizing plate, high-contrast display can be provided.

Accordingly, as shown in FIG. 25B, an active matrix EL display device having a structure including a p-channel TFT 812, an n-channel TFT 813, a sampling circuit TFT 814, a switching TFT 815, and a current-control TFT 816 is completed. In the present embodiment, the p-channel TFT 812 and the current-control TFT 816 each without an LDD region, the n-channel TFT 813 having a Lov region, the switching TFT 815 having a Loff region, and the sampling circuit TFT 814 having both a Loff region and a Lov region can be formed concurrently over the same substrate. It is to be noted that the p-channel TFTs 812 and 816 have little hot carrier effect and have little short channel effect; therefore, an LDD region is not provided in the present embodiment. L However, as in other n-channel TFTs, the p-channel TFT can be provided appropriately with an LDD region by doping of a p-type impurity element with the use of a gate electrode or a sidewall as a mask. As for the method, p-channel TFTs having each structure can be formed by referring to the method for forming the n-channel TFTs of the present embodiment and using a p-type impurity element as a doping element.

In the present embodiment, a bottom-emission EL display device is described, in which a pixel electrode is a transparent conductive film and the other electrode is an MgAg electrode. However, the present invention is not limited to this structure, and a top-emission EL display device may be manufactured by forming a pixel electrode with a light-shielding material and forming the other electrode with a transparent conductive film. In addition, a dual-emission EL display device may be manufactured by forming the both electrodes with a transparent conductive film.

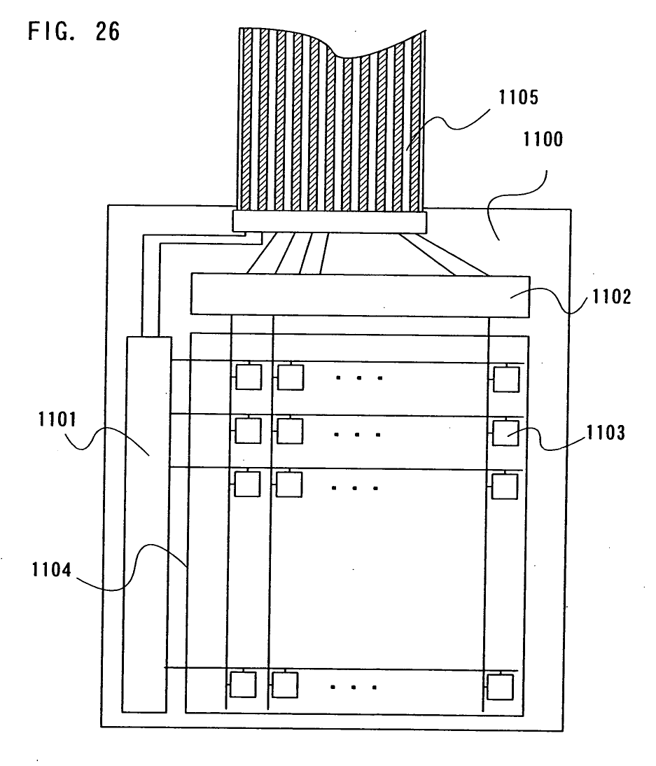

FIG. 26 shows a schematic view of a display device. A gate-signal line driver circuit 1101, a source-signal line driver circuit 1102, and a pixel portion 1104 having a plurality of pixels 1103 are formed over a substrate 1100. The gate-signal line driver circuit 1101 and the source-signal line driver circuit 1102 are connected to an FPC (Flexible Printed Circuit) 1105. The p-channel TFT 812 and the n-channel TFT 813 each shown in FIG. 25B can be used for the source-signal line driver circuit or the gate-signal line driver circuit.

The source-signal line driver circuit 1102 includes a shift register circuit, a level shifter circuit, and a sampling circuit. A clock signal (CLK) and a start pulse signal (SP) are inputted into the shift register circuit, which outputs a sampling signal for sampling a video signal. The sampling signal outputted from the shift register is inputted into the level shifter circuit, and the signal is amplified. The amplified sampling signal is then inputted into the sampling circuit. The sampling circuit samples a video signal inputted from the outside by the sampling signal and inputs it into the pixel portion.

As for such driver circuits, a high-speed operation is required; therefore, a TFT having a GOLD structure is preferably used. This is because a Lov region has a function to relieve a high electric field generated in the vicinity of a drain, and can prevent deterioration due to hot carriers. In addition, since, as for a sampling circuit, a measure against deterioration due to hot carriers and a low OFF current are required, a structure having both of a Lov region and a Loff region is preferable. On the other hand, a switching TFT for a pixel or a storage TFT for storing a gate voltage of a current control TFT is preferably formed of a TFT having a Loff region that is capable of lowering an OFF current.

In view of the present embodiment through the above aspects, the n-channel TFTs in the driver circuit portion each have a Lov region, the sampling circuit TFT has a Loff region and a Lov region, and the switching TFT of the pixel portion has a Loff region. TFTs suitable for various circuits can be manufactured with high accuracy in accordance with the present embodiment. Therefore, a semiconductor device manufactured in the present embodiment is to be a display device capable of a high-speed operation with less leak-current. In addition, the semiconductor device of the present embodiment can be compact; thus, a small display device that is easily carried out can be realized.

The present invention is not limited to a display device having the above structure and can be applied in manufacturing various display devices as a matter of course.

### Embodiment 12

In the present embodiment, an example of manufacturing a liquid crystal display device according to the present invention will be described. Further, in the present embodiment, the same reference numerals are used for the same portions as in Embodiments 1 to 11, and a detailed explanation is omitted.

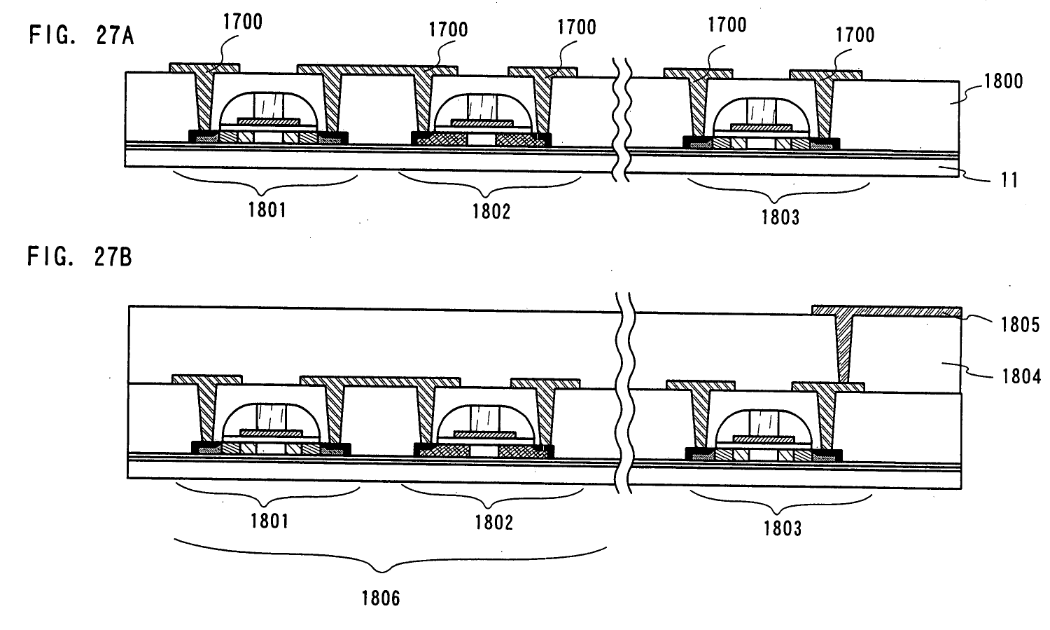

Through the same steps as in Embodiment 11 shown in FIGS. 22A to 22C, 23A to 23C, 24A to 24C, and 25A and 25B, n-channel TFTs 1801 and 1803 having a Lov region and a Loff region, and a p-channel TFT 1802 without a LDD structure are formed over a substrate 11 (FIG. 27A). However, each structure of the n-channel TFT and the p-channel TFT is not limited the above structure, and any of the structures described in Embodiments 1 to 6 can be employed. For example, the n-channel TFT 1803 may have the structure described in Embodiment 2 or 3. An interlayer insulating film 1800 contains an inorganic material or an organic material, and has a single layer structure or a stacked layer structure.

Next, an interlayer insulating film 1804 is further formed over the interlayer insulating film 1800 and wirings 1700. Then, a resist mask is formed by using a photomask, and the interlayer insulating film 1804 is partially removed by dry etching so as to form an opening (a contact hole). In the formation of this contact hole, carbon tetrafluoride (CF₄), oxygen (O₂) and helium (He) are used as an etching gas with a flow rate of CF₄:O₂:He=50:50:30 (sccm). It is to be noted that the bottom of the contact hole reaches the wiring 1700 connected to the n-channel TFT 1803.

Then, after removing the resist mask, a conductive film is formed over the entire surface and etching is conducted to form a pixel electrode 1805 which is electrically connected to the n-channel TFT 1803 (FIG. 27B). In the present embodiment, a reflective liquid crystal display panel is manufactured; therefore, the pixel electrode 1805 is formed by sputtering using a light-reflective metal material such as Ag (silver), Au (gold), Cu (copper), W (tungsten) or Al (aluminum).

In the case of manufacturing a light-transmissive liquid crystal display panel, the pixel electrode 1805 is formed by using a transparent conductive film such as indium tin oxide (ITO), indium tin oxide containing silicon oxide, zinc oxide (ZnO) or tin oxide (SnO₂).

Through the above steps, a TFT substrate of a liquid crystal display device is completed, in which the n-channel TFT 1803 that is a TFT of the pixel portion, a CMOS circuit 1806 including the n-channel TFT 1801 and the p-channel TFT 1802, and the pixel electrode 1805 are formed over the substrate 11.

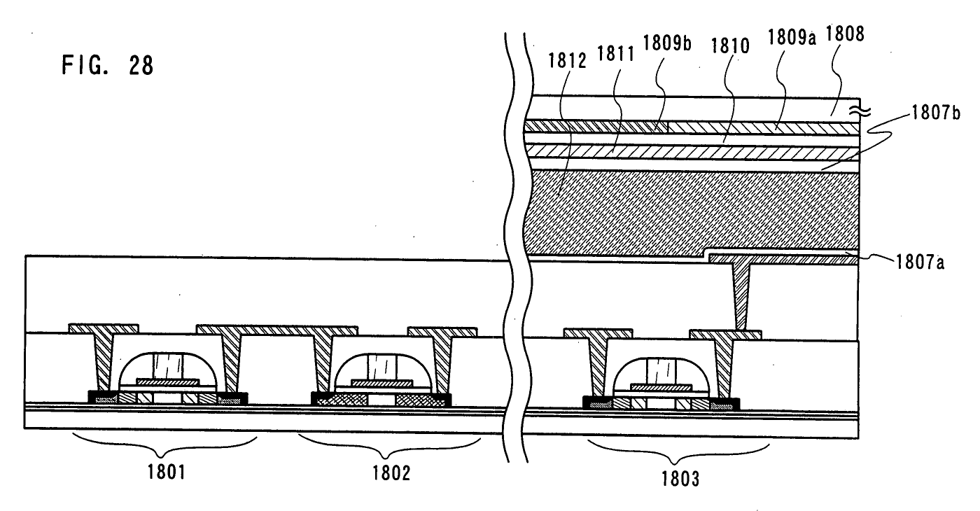

Then, an alignment film 1807a is formed to cover the pixel electrode 1805 as shown in FIG. 28. It is to be noted that the alignment film 1807a may be formed by a droplet discharge method, screen printing or offset printing. Thereafter, rubbing process is conducted to the surface of the alignment film 1807a.

Over a counter substrate 1808, a color filter formed of a colored layer 1809a, a light-shielding layer (black matrix) 1809b and an overcoat layer 1810 is provided, and a counter electrode 1811 formed of a transparent electrode or a reflective electrode is formed, and then, the alignment film 1807b is formed thereover. Although not shown here, a sealing material is formed to surround a region overlapping with the pixel portion including the n-channel TFT 1803 that is a pixel TFT by a droplet discharge method.

Then, a liquid crystal composition 1812 is dropped at a reduced pressure so that bubbles are not mixed therein, and both the substrates 11 and 1808 are attached to each other. As an alignment mode of the liquid crystal composition 1812, a TN mode is used, in which the alignment of liquid crystal molecules is twist-aligned by 90° from the light injection point to the light emission point. The substrates are attached to each other in such a manner that the rubbing directions thereof intersect with each other at right angles.

It is to be noted that the distance between a pair of the substrates may be kept even by dispersing a spherical spacer or providing a columnar spacer formed of a resin, or by providing a filler in the sealing material. The aforementioned columnar spacer is formed by using an organic resin material containing at least one of acrylic, polyimide, polyimide amide and epoxy as its main component, or an inorganic material having any of silicon oxide, silicon nitride and silicon oxide containing nitrogen, or a stacked film thereof.

As described above, a compact liquid crystal display device having a longer life can be formed in the present embodiment. The liquid crystal display device manufactured in the present embodiment can be used as a display portion of various electronic devices.

In the present embodiment, the TFT having a single gate structure is described; however, the present invention is not limited to the single gate structure, and a multi gate TFT having a plurality of channel formation regions such as a double gate TFT may also be employed.

### Embodiment 13

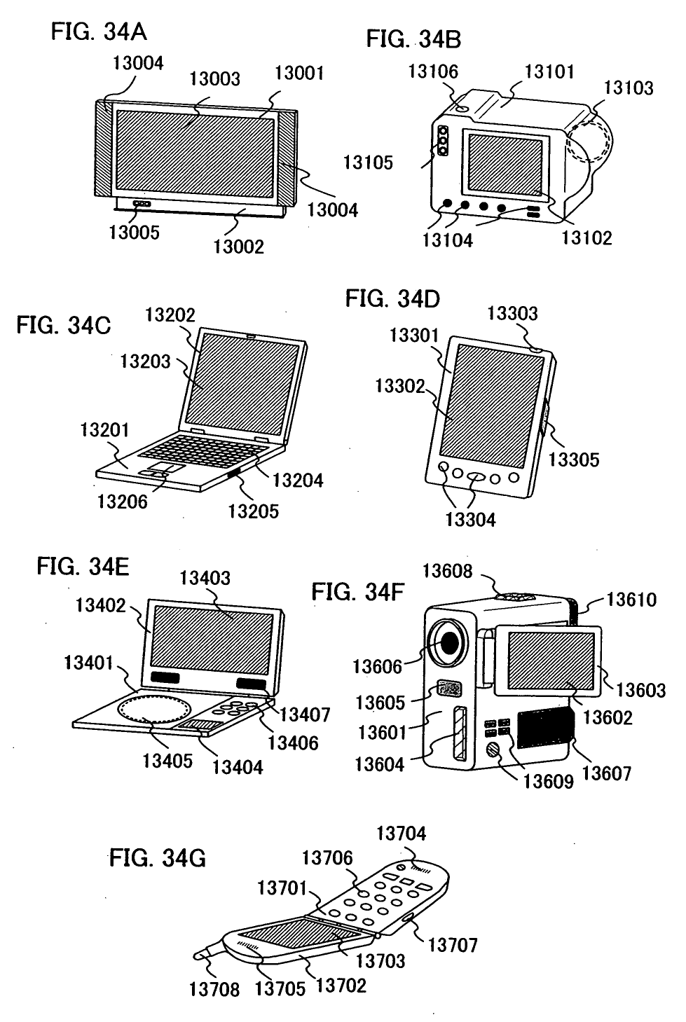

The semiconductor devices shown in Embodiments 1 to 10 and the display devices shown in Embodiments 11 and 12 can be used in manufacturing various electronic devices. Such electronic devices include, for example, a television device, a video camera, a digital camera, a navigation system, an audio reproducing device (a car audio, an audio component, and the like), a personal computer, a game machine, a portable information terminal (a mobile computer, a cellular phone, a portable game machine, an electronic book, and the like), an image reproducing device provided with a recording medium (specifically, a device capable of reproducing a recording medium such as a Digital Versatile Disk (DVD) and having a display capable of displaying the image), and the like. Specific examples of such electronic devices are shown in FIGS. 34A to 34G.

FIG. 34A shows a television device, which includes a housing 13001, a supporting stand 13002, a display portion 13003, speaker portions 13004, a video input terminal 13005, and the like. The display device described in Embodiments 11 and 12 can be applied to the display portion 13003, and the television device can be completed. As the display portion 13003, an EL display, a liquid crystal display, or the like can be used. It is to be noted that the television device includes all television sets such as the ones for a computer, TV broadcast reception, and advertisement display. By the above structure, a driver circuit portion can be compact, and an inexpensive television device with high reliability can be provided.

FIG. 34B shows a digital camera, which includes a main body 13101, a display portion 13102, an image receiving portion 13103, operation keys 13104, an external connecting port 13105, a shutter 13106, and the like. The display device described in Embodiments 11 and 12 can be applied to the display portion 13102, and the digital camera can be completed. By the above structure, the display portion 13102 can be compact, and an inexpensive and compact digital camera with high reliability can be provided.

FIG. 34C shows a computer, which includes a main body 13201, a housing 13202, a display portion 13203, a keyboard 13204, an external connecting port 13205, a pointing mouse 13206, and the like. The display device described in Embodiments 11 and 12 can be applied to the display portion 13203, and the computer can be completed. By the above structure, the display portion 13203 can be compact, and an inexpensive and compact computer with high reliability can be provided.

FIG. 34D shows a mobile computer, which includes a main body 13301, a display portion 13302, a switch 13303, operation keys 13304, an IR port 13305, and the like. The display device described in Embodiments 11 and 12 can be applied to the display portion 13302, and the mobile computer can be completed. By the above structure, the display portion 13302 can be compact, and an inexpensive and compact mobile computer with high reliability can be provided.

FIG. 34E shows an image reproducing device provided with a recording medium (specifically, a DVD reproducing device), which includes a main body 13401, a housing 13402, a display portion A 13403, a display portion B 13404, a recording medium (a DVD and the like) reading portion 13405, operation keys 13406, a speaker portion 13407, and the like. The display portion A 13403 mainly displays image information while the display portion B 13404 mainly displays text information. The display device described in Embodiments 11 and 12 can be applied to the display portion A 13403 and the display portion B 13404, and the image reproducing device can be completed. It is to be noted that the image reproducing device provided with a recording medium includes a game machine and the like. By the above structure, the display portions can be compact, and an inexpensive and compact image reproducing device with high reliability can be provided.

FIG. 34F shows a video camera, which includes a main body 13601, a display portion 13602, a housing 13603, an external connecting port 13604, a remote controller receiving portion 13605, an image receiving portion 13606, a battery 13607, an audio input portion 13608, operation keys 13609, an eye piece 13610, and the like. The display device described in Embodiments 11 and 12 can be applied to the display portion 13602, and the video camera can be completed. By the above structure, the display portion 13602 can be compact, and an inexpensive and compact video camera with high reliability can be provided.

FIG. 34G shows a cellular phone, which includes a main body 13701, a housing 13702, a display portion 13703, an audio input portion 13704, an audio output portion 13705, operation keys 13706, an external connecting port 13707, an antenna 13708, and the like. The display device described in Embodiments 11 and 12 can be applied to the display portion 13703, and the cellular phone can be completed. It is to be noted that current consumption of the cellular phone can be suppressed by displaying white text on a black background in the display portion 13703. By the above structure, the display portion 13703 can be compact, and an inexpensive and compact cellular phone with high reliability can be provided.

In particular, the display device used for the display portion of such electronic devices includes thin film transistors for driving pixels, and desired structures of the TFTs differ from each other depending on the circuit. By applying the present invention, TFTs having suitable structures for the various circuits can be manufactured with high accuracy; therefore, a high-quality electronic device can be manufactured with high yield.

As described above, the applicable range of the present invention is extremely wide, and the invention can be applied to electronic devices of various fields.

### Example 1

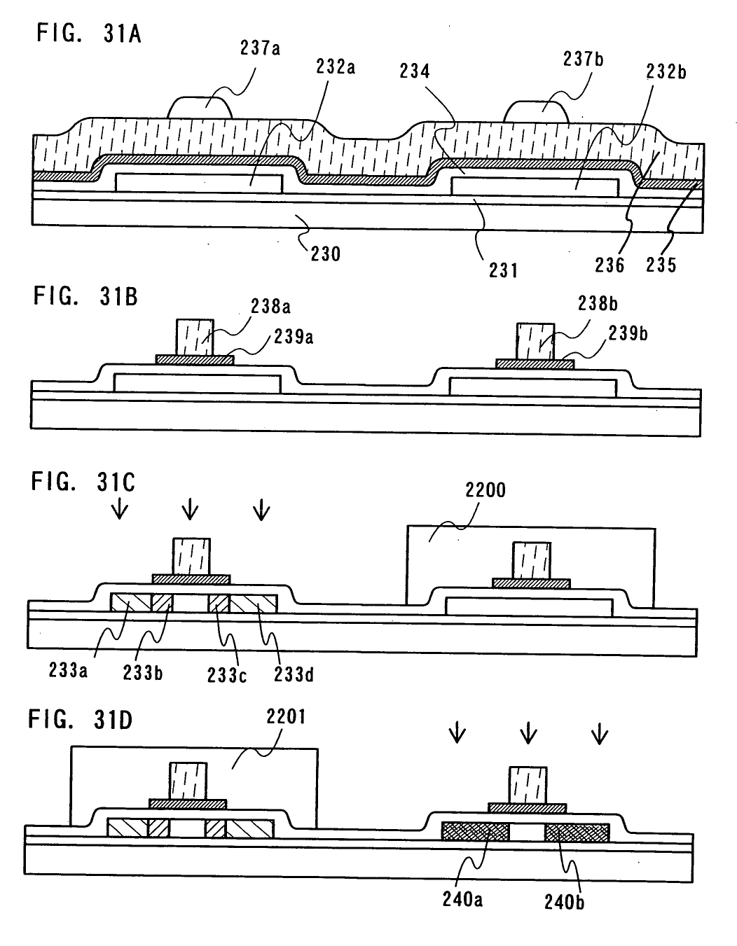

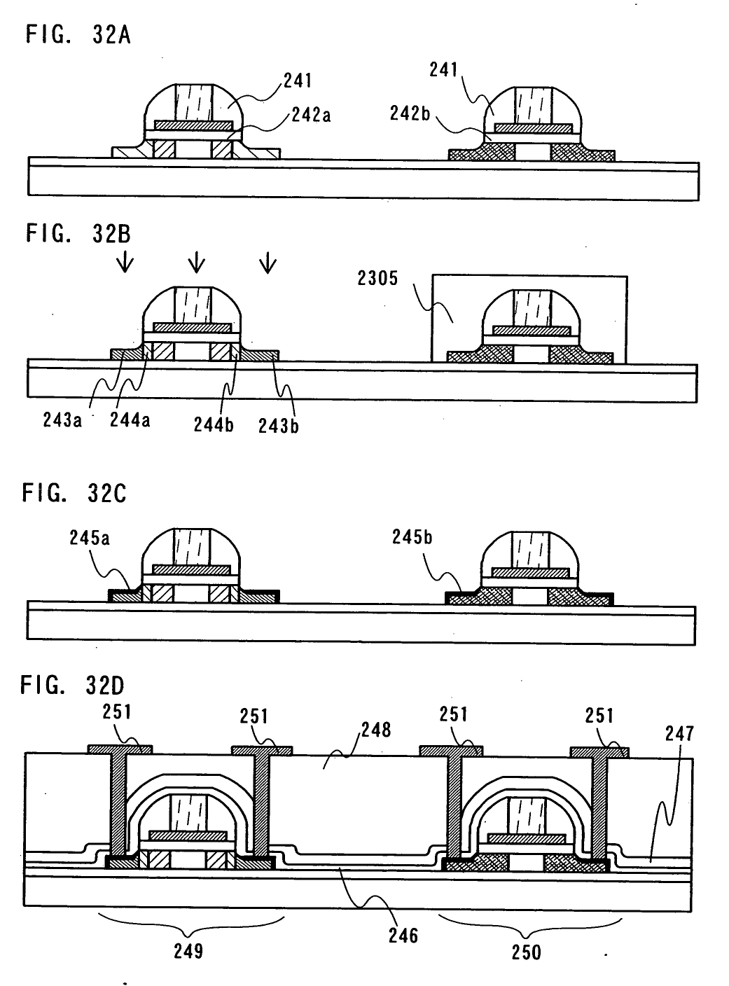

A specific method for forming an n-channel TFT and a p-channel TFT over the same substrate will be described with reference to FIGS. 31A to 31D, and 32A to 32D.

A glass substrate is used as a substrate 230 (FIG. 31A). Over the glass substrate, a base film 231 is formed by stacking a silicon oxide film containing nitrogen (a SiON film) and a silicon nitride film containing oxygen (a SiNO film) by CVD. The SiNO film is 50 nm thick and the SiON film is 100 nm thick.

Then, over the base film, an amorphous silicon film is formed to be 60 to 70 nm by CVD as a semiconductor film. The amorphous silicon film is heated at 500 to 550° C. to release hydrogen from the film. The amorphous silicon is then crystallized by irradiation of a continuous wave laser. Thereafter, doping of the small amount of B₂H₆ is conducted by channel doping to the entire surface of the crystallized silicon film.

Subsequently, the crystallized silicon film is etched to form island-shaped semiconductor films 232a and 232b. Over the island-shaped semiconductor films, a SiON film of 40 nm thick is formed by CVD as a gate insulating film 234. Over the gate insulating film 234, a tantalum nitride layer of 30 nm thick is formed by sputtering as a first conductive film 235, and a tungsten film of 370 nm is formed by sputtering as a second conductive film 236. Then, resists 237a and 237b are formed by using a stepper over the tungsten film.

Next, although not shown here, the tungsten film is etched by using the resists 237a and 237b as masks to form gate electrodes from the tungsten film. A mixed gas of Cl₂, SF₆, and O₂ is used as an etching gas, and the flow rate is Cl₂/SF₆/O₂=33/33/10 (sccm). Plasma is generated by adjusting pressure to be 0.67 Pa and applying power of 2000 W to a coil-shaped electrode. Power of 50 W is applied to a substrate side (sample stage).

Then, by using the gate electrodes formed of the tungsten film formed by the above etching as masks, the tantalum nitride film is etched to form first gate electrodes 239a and 239b that are formed of the tantalum nitride film. An etching gas is Cl₂. Plasma is generated by adjusting pressure to be 0.67 Pa and applying power of 2000 W to a coil-shaped electrode. Power of 50 W is applied to a substrate side (sample stage).

Next, the resists are recessed by etching. By using the recessed resists as masks, the gate electrodes formed of tungsten are etched. Plasma is generated by adjusting pressure to be 1.33 Pa and applying power of 2000 W to a coil-shaped electrode. Power is not applied to a substrate side (sample stage). A mixed gas of Cl₂, SF₆, and O₂ is used as an etching gas, and the flow rate is Cl₂/SF₆/O₂=22/22/30 (sccm). Accordingly, second gate electrodes 238a and 238b are formed of tungsten. Thereafter, the resists are removed (FIG. 31B).

Next, the island-shaped semiconductor film 232a which becomes an n-channel TFT is doped with PH₃ in a low-concentration by an acceleration voltage of 80 kV so that phosphorus concentration is 5.0×10¹³ atoms/cm³. At this time, a p-channel TFT is covered with a resist 2200 so as not to be doped with PH₃ (FIG. 31C). After the doping, the resist 2200 is removed. By this doping, n-type low-concentration impurity regions 233a to 233d are formed.

Then, the island-shaped semiconductor film 232b which becomes a p-channel TFT is doped with boron in a high-concentration by an acceleration voltage of 45 kV (FIG. 31D). The boron concentration is to be 3.0×10²⁰ atoms/cm³. At this time, the n-channel TFT is covered with a resist 2201 so as not to be doped with boron. After the doping, the resist 2201 is removed. By this doping, p-type high-concentration impurity regions 240a and 240b are formed.

Subsequently, a silicon oxide film is formed isotropically to be 300 nm thick by CVD, and the silicon oxide film is etched back by anisotropic etching to form sidewalls 241 (FIG. 32A). Then, by using the sidewalls 241 as masks, the SiON film that is the gate insulating film 234 is etched by dry etching (FIG. 32A). Accordingly, gate insulating films 242a and 242b are formed.

Then, the island-shaped semiconductor films exposed from the gate insulating films 242a and 242b are doped with phosphorus in a high-concentration by an acceleration voltage of 20 kV so that phosphorus is included in a concentration of 3.0×10¹⁵ atoms/cm³. Also in this case, the p-channel TFT is covered with a resist 2305 so as not to be doped with phosphorus. By this doping, n-type low-concentration impurity regions 244a and 244b, and n-type high-concentration impurity regions 243a and 243b are formed. After the doping, the resist 2305 is removed (FIG. 32B).

Next, after a nickel film of 5 nm is formed as a metal film over the entire surface by sputtering at a room temperature, a heat treatment is conducted at 500° C. for 30 seconds by using RTA (Rapid Thermal anneal). This heat treatment is conducted in vacuum. By this treatment, nickel and silicon in the semiconductor film react with each other, and silicide layers 245a and 245b formed of nickel silicide are formed over the surface of the exposed island-shaped semiconductor films (FIG. 32C).

The remained nickel is removed by wet etching. Then, a SiON film 246 is formed to have a film thickness of 50 nm over the entire surface by CVD. Thereafter, a heat treatment is conducted in a nitrogen atmosphere at 550° C. for 4 hours by using a furnace to conduct thermal activation of the impurity regions. The SiON film 246 serves as a cap film for preventing oxidation of tungsten due to the thermal activation.

Subsequently, a silicon nitride film 247 of 100 nm and a SiON film 248 of 600 nm are stacked over the SiON film 246 sequentially. The SiON film 246, the silicon nitride film 247 and the SiON film 248 become an interlayer insulating film. Thereafter, a heat treatment is conducted in a nitrogen atmosphere at 410° C. for one hour. By the heat treatment, hydrogen is released from the silicon nitride film 247, thereby conducting hydrogenation of the semiconductor film.

Then, the interlayer insulating film is etched by dry etching to form contact holes which expose the silicide layers 245a and 245b. Then, a conductive layer is formed of a stacked layer by sequential deposition using sputtering so that contact holes are filled. The conductive layer has a stacked layer structure of a titanium film of 60 nm, a titanium nitride film of 40 nm, an aluminum film of 500 nm, a titanium film of 60 nm, and a titanium nitride film of 40 nm. This conductive layer is etched by dry etching to form wirings 251 that become a source electrode and a drain electrode (FIG. 32D). Through the above steps, an n-channel TFT 249 and a p-channel TFT 250 are formed.

In the n-channel TFT 249, the low-concentration impurity regions 233a and 233c are Lov regions, the low-concentration impurity regions 244a and 244b are Loff regions, and the high-concentration impurity regions 243a and 243b are a source region and a drain region. On the other hand, the p-channel TFT has only the high-concentration impurity regions 240a and 240b as a source region and a drain region, and does not have an LDD region.

The present example can be arbitrarily combined with Embodiments 1 to 13. This application is based on Japanese Patent Application serial no. 2005-62929 filed in Japan Patent Office on Mar. 7, 2005, the entire contents of which are hereby incorporated by reference.

What is claimed is:

1. A semiconductor device comprising:
a semiconductor film formed over a substrate, said semiconductor film including a channel formation region, a low-concentration impurity region, and a high-concentration impurity region;
a gate insulating film which is formed so that a part of the high-concentration impurity region is exposed;
a gate electrode formed over the gate insulating film, said gate electrode including a first conductive film and a second conductive film formed over the first conductive film;
sidewalls formed on side surfaces of the gate electrode;
a silicide layer formed on a surface of the high-concentration impurity region; and
a wiring connected to the silicide layer,
wherein a side edge of the gate insulating film in a channel length direction and an outer side edge of one of the sidewalls are in alignment;
wherein the first conductive film has a longer length in a channel length direction than that of the second conductive film; and
wherein the low-concentration impurity region overlaps with the first conductive film with the gate insulating film interposed therebetween, and does not overlap with the second conductive film.

2. A semiconductor device comprising:
a semiconductor film formed over a substrate, said semiconductor film including a channel formation region, a first low-concentration impurity region, a second low-concentration impurity region, and a high-concentration impurity region;
a gate insulating film which is formed so that the high-concentration impurity region is exposed;
a gate electrode formed over the gate insulating film, said gate electrode including a first conductive film and a second conductive film formed over the first conductive film;
sidewalls formed on side surfaces of the gate electrode;
a silicide layer formed on a surface of the high-concentration impurity region; and
a wiring connected to the silicide layer,
wherein a side edge of the gate insulating film in a channel length direction and an outer side edge of one of the sidewalls are in alignment;
wherein the first conductive film has a longer length in a channel length direction than that of the second conductive film;
wherein the first low-concentration impurity region overlaps with the first conductive film with the gate insulating film interposed therebetween, and does not overlap with the second conductive film; and
wherein the second low-concentration impurity region overlaps with one of the sidewalls with the gate insulating film interposed therebetween, and does not overlap with the first conductive film.

3. The semiconductor device according to claim 1, wherein a length of the low-concentration impurity region in the channel length direction is 20 nm or more to 200 nm or less.

4. The semiconductor device according to claim 2, wherein a length of the first low-concentration impurity region in the channel length direction is 20 nm or more to 200 nm or less, and a length of the second low-concentration impurity region in the channel length direction is 30 nm or more to 500 nm or less.

5. The semiconductor device according to claim 1, wherein a channel length of the channel formation region is 0.1 μm or more to 1.0 μm or less.

6. The semiconductor device according to claim 2, wherein a channel length of the channel formation region is 0.1 μm or more to 1.0 μm or less.

7. A method for manufacturing a semiconductor device, comprising the steps of:
forming a gate insulating film over a semiconductor film including silicon over a substrate;
forming a first conductive film over the gate insulating film;
forming a second conductive film over the first conductive film;
forming a resist over the second conductive film;
forming an etched second conductive film by conducting a first etching to the second conductive film by using the resist as a mask;
forming a first gate electrode by conducting a second etching to the first conductive film by using the resist and the etched second conductive film as masks;
forming a second gate electrode having the shorter gate length than that of the first gate electrode by conducting a third etching to the etched second conductive film to recess the resist and etch the etched second conductive film by using the recessed resist as a mask;
forming a channel formation region and a low-concentration impurity region in the semiconductor film by conducting doping of an impurity element using the second gate electrode as a mask;
forming sidewalls on side surfaces of the first gate electrode and side surfaces of the second gate electrode;
exposing a part of the semiconductor film by etching the gate insulating film by using the sidewalls and the second gate electrode as masks;
forming a metal film to be in contact with at least the exposed part of the semiconductor film;
conducting a heat treatment after forming the metal film to form a silicide layer in the exposed part of the semiconductor film, which is in contact with the metal film; and
forming a high-concentration impurity region in the semiconductor film by conducting doping of an impurity element using the sidewalls and the second gate electrode as masks.

8. A method for manufacturing a semiconductor device, comprising the steps of:
forming a gate insulating film over a semiconductor film including silicon over a substrate;
forming a first conductive film over the gate insulating film;
forming a second conductive film over the first conductive film;
forming a resist over the second conductive film;
forming an etched second conductive film by conducting a first etching to the second conductive film by using the resist as a mask;
forming a first gate electrode by conducting a second etching to the first conductive film by using the resist and the etched second conductive film as masks;
forming a second gate electrode having the shorter gate length than that of the first gate electrode by conducting a third etching to the etched second conductive film to recess the resist and etch the etched second conductive film by using the recessed resist as a mask;
forming a channel formation region, a low-concentration impurity region and a high-concentration region in the semiconductor film by conducting doping of an impurity element using the second gate electrode as a mask;
forming sidewalls on side surfaces of the first gate electrode and side surfaces of the second gate electrode;
exposing a part of the semiconductor film by etching the gate insulating film by using the sidewalls and the second gate electrode as masks;
forming a metal film to be in contact with at least the exposed part of the semiconductor film; and
conducting a heat treatment after forming the metal film to form a silicide layer in the exposed part of the semiconductor film, which is in contact with the metal film.

9. A method for manufacturing a semiconductor device, comprising the steps of:
forming a gate insulating film over a semiconductor film including silicon over a substrate;
forming a first conductive film over the gate insulating film;
forming a second conductive film over the first conductive film; forming a resist over the second conductive film;
forming an etched second conductive film by conducting a first etching to the second conductive film by using the resist as a mask;
forming a first gate electrode by conducting a second etching to the first conductive film by using the resist and the etched second conductive film as masks;
forming a second gate electrode having a shorter gate length than that of the first gate electrode by conducting a third etching to the etched second conductive film to recess the resist and etch the etched second conductive film by using the recessed resist as a mask;
forming a channel formation region, a low-concentration impurity region and a high-concentration impurity region in the semiconductor film by conducting doping of an impurity element using the second gate electrode as a mask;
forming a third gate electrode having the same gate length as the second gate electrode by etching the first gate electrode by using the second gate electrode as a mask;
exposing a part of the semiconductor film by etching the gate insulating film by using the second gate electrode and the third gate electrode as masks;
forming sidewalls on side surfaces of the etched gate insulating film, side surfaces of the second gate electrode and side surfaces of the third gate electrode;
forming a metal film to be in contact with at least the exposed part of the semiconductor film; and
conducting a heat treatment after forming the metal film to form a silicide layer in the exposed part of the semiconductor film, which is in contact with the metal film.

10. A method for manufacturing a semiconductor device, comprising the steps of:
forming a gate insulating film over a semiconductor film including silicon over a substrate;
forming a first conductive film over the gate insulating film;
forming a second conductive film over the first conductive film;
forming a resist over the second conductive film;
forming an etched second conductive film by conducting a first etching to the second conductive film by using the resist as a mask;
forming a first gate electrode by conducting a second etching to the first conductive film by using the resist and the etched second conductive film as masks;
forming a second gate electrode having a shorter gate length than that of the first gate electrode by conducting a third etching to the etched second conductive film to recess the resist and etch the etched second conductive film by using the recessed resist as a mask;
exposing a part of the semiconductor film by etching the gate insulating film by using the first gate electrode as a mask;
forming a channel formation region and a low-concentration impurity region by conducting doping of an impurity element by using the second gate electrode as a mask before or after etching the gate insulating film;
forming sidewalls on side surfaces of the etched gate insulating film, side surfaces of the first gate electrode and side surfaces of the second gate electrode;
forming a metal film to be in contact with at least the exposed part of the semiconductor film; and
conducting a heat treatment after forming the metal film to form a silicide layer in the exposed part of the semiconductor film, which is in contact with the metal film.

11. The method for manufacturing a semiconductor device according to claim 7, wherein the channel length of the channel formation region is 0.1 μm or more to 1.0 μm or less.

12. The method for manufacturing a semiconductor device according to claim 8, wherein the channel length of the channel formation region is 0.1 μm or more to 1.0 μm or less.

13. The method for manufacturing a semiconductor device according to claim 9, wherein the channel length of the channel formation region is 0.1 μm or more to 1.0 μm or less.

14. The method for manufacturing a semiconductor device according to claim 10, wherein the channel length of the channel formation region is 0.1 μm or more to 1.0 μm or less.

15. The method for manufacturing a semiconductor device according to claim 7, wherein a wiring connected to the silicide layer is formed.

16. The method for manufacturing a semiconductor device according to claim 8 wherein a wiring connected to the silicide layer is formed.

17. The method for manufacturing a semiconductor device according to claim 9, wherein a wiring connected to the silicide layer is formed.

18. The method for manufacturing a semiconductor device according to claim 10, wherein a wiring connected to the silicide layer is formed.
